(19) United States
(12) Patent Application Publication
(10) Pub. No.: US 2025/0017012 A1
(43) Pub. Date: Jan. 9, 2025

(54) NOR MEMORY DEVICE AND MANUFACTURING METHOD THEREOF

(71) Applicant: GIGADEVICE SEMICONDUCTOR INC., Beijing (CN)

(72) Inventors: Xiao LUO, Beijing (CN); Jun FENG, Beijing (CN); Yisheng XU, Beijing (CN); Linkai WANG, Beijing (CN)

(21) Appl. No.: 18/764,213

(22) Filed: Jul. 4, 2024

(30) Foreign Application Priority Data
Jul. 6, 2023 (CN) 202310826763.0

(51) Int. Cl. H10B 43/27; H01L 29/417; H10B 41/10; H10B 41/27; H10B 43/10

(52) U.S. Cl. CPC H10B 43/27; H01L 29/41725; H10B 41/10; H10B 41/27; H10B 43/10

(57) ABSTRACT

Disclosed is NOR memory device. The NOR memory device comprises: at least two source/drain contact layers and at least one isolation layer alternately stacked in a vertical direction; a gate structure vertically extending through the source/drain contact layers and the isolation layer; and a semiconductor layer on the periphery of the gate structure; wherein, two of the source/drain contact layers located immediately above and below the isolation layer are respectively connected to two bit/source lines, and form a memory transistor together with the gate structure and the semiconductor layer.

### CROSS-REFERENCE TO RELATED APPLICATIONS

This application claims priority to Chinese patent application No. 202310826763.0 filed on Jul. 6, 2023, the disclosure of which is incorporated herein by reference in its entirety and for all purposes.

### TECHNICAL FIELD

The disclosure herein relates to the field of integrated circuits, and in particular, to a NOR memory device.

### BACKGROUND

Currently, there are two common types of flash memory: NOR and NAND, where the former includes memory cells connected in parallel while the latter includes memory cells connected in series. Due to the difference in the circuit structure of memory cells, it is difficult to improve the integration density of memory cells in NOR memory compared to NAND memory.

Therefore, many new designs have been proposed to improve the integration density of memory cells in NOR memory.

### SUMMARY

According to some embodiments of the present disclosure, a NOR memory device is provided, comprising: at least two source/drain contact layers and at least one isolation layer alternately stacked in a vertical direction; a gate structure vertically extending through the source/drain contact layers and the isolation layer; and a semiconductor layer on the periphery of the gate structure; wherein, two of the source/drain contact layers located immediately above and below the isolation layer are respectively connected to two bit/source lines, and form a memory transistor together with the gate structure and the semiconductor layer.

According to some embodiments of the present disclosure, a method of manufacturing a NOR memory device is provided, comprising: forming, over a substrate, at least two source/drain contact layers and at least one isolation layer alternately stacked in a vertical direction; forming a gate hole that extends vertically through the source/drain contact layers and the isolation layer; forming, in the gate hole, a gate structure and a semiconductor layer on the periphery of the gate structure; and connecting two of the source/drain contact layers located immediately above and below the isolation layer to two bit/source lines respectively; wherein, the two source/drain contact layers located immediately above and below the isolation layer form a memory transistor together with the gate structure and the semiconductor layer.

### BRIEF DESCRIPTION OF FIGURES

The above and other objects, features and advantages of the present disclosure will become more apparent from the more detailed description of the exemplary embodiments of the present disclosure taken in conjunction with the accompanying drawings, wherein the same reference numerals generally refer to the same parts in exemplary embodiments of the present disclosure.

FIG. 1A shows an exemplary structure of a NOR memory device according to at least one embodiment of the present disclosure in a cross-sectional view, and FIG. 1B shows a top view of the NOR memory device in FIG. 1A in the case of removing its interlayer dielectric layer.

FIG. 2A shows an exemplary structure of a NOR memory device according to at least one embodiment of the present disclosure in a cross-sectional view, and FIG. 2B shows a top view of the NOR memory device in FIG. 2A in the case of removing its interlayer dielectric layer.

FIG. 3A shows a schematic plan view of an array composed of NOR memory devices according to at least one embodiment of the present disclosure, FIG. 3B shows a schematic cross-sectional view taken along the dashed line A-A as shown in FIG. 3A, and FIG. 3C shows a schematic cross-sectional view taken along the dashed line B-B as shown in FIG. 3A.

FIG. 4A shows a schematic plan view of an array composed of NOR memory devices according to at least one embodiment of the present disclosure, FIG. 4B shows a schematic cross-sectional view taken along the dashed line A2-A2 as shown in FIG. 4A, and FIG. 4C shows a schematic cross-sectional view taken along the dashed line B2-B2 as shown in FIG. 4A.

FIG. 5A shows a schematic plan view of an array composed of NOR memory devices according to at least one embodiment of the present disclosure, FIG. 5B shows a schematic plan view of another array composed of NOR memory devices according to at least one embodiment of the present disclosure, FIG. 5C shows a schematic cross-sectional view taken along the dashed line A3-A3 as shown in FIG. 5B, and FIG. 5D shows a schematic cross-sectional view taken along the dashed line B3-B3 as shown in FIG. 5B.

FIG. 6 shows a circuit schematic diagram of a NOR memory array according to at least one embodiment of the present disclosure.

FIG. 7 shows a circuit schematic diagram of an exemplary write operation performed on a memory array therein by a NOR memory according to at least one embodiment of the present disclosure.

FIG. 8 shows a circuit schematic diagram of an exemplary write operation performed on a memory array therein by a NOR memory according to at least one embodiment of the present disclosure.

FIG. 9 shows a circuit schematic diagram of an exemplary read operation performed on a memory array therein by a NOR memory according to at least one embodiment of the present disclosure.

FIG. 10A shows a schematic plan view of an array composed of NOR memory devices according to at least one embodiment of the present disclosure, FIG. 10B shows a schematic cross-sectional view taken along the dashed line A4-A4 as shown in FIG. 10A, and FIG. 10C shows a schematic cross-sectional view taken along the dashed line B4-B4 as shown in FIG. 10A.

FIG. 11 shows a circuit schematic diagram of a NOR memory array according to at least one embodiment of the present disclosure.

FIGS. 12A to 12G are cross-sectional views schematically illustrating respective steps of a method for manufacturing a NOR memory device according to at least one embodiment of the present disclosure.

FIGS. 13A to 13I are cross-sectional views schematically illustrating respective steps of a method for manufacturing a NOR memory device according to at least one embodiment of the present disclosure.

### DETAILED DESCRIPTION

Some embodiments of the present disclosure will be described in more detail below with reference to the accompanying drawings. Although the embodiments of the present disclosure are shown in the drawings, it should be understood that the present disclosure may be embodied in various forms and should not be limited to the embodiments set forth herein. Rather, these embodiments are provided so that this disclosure will be thorough and complete, and will fully convey the scope of the disclosure to those skilled in the art.

It is understood that, the terms “first” and “second” in this disclosure and the like are only used for descriptive purposes and would not be understood as indicating or implying relative importance or implying the quantity of technical features indicated. Therefore, the feature having the limitation of “first”, “second” or the like may explicitly or implicitly include one or more of the said features. In the description of this disclosure, the meaning of “multiple”, “a plurality of” or the like refers to two or more, unless otherwise specified.

In the description of this disclosure, it is noted that, unless otherwise specified and limited, the terms “install”, “mount”, “fit”, “connect”, “couple” or the like should be understood broadly; for example, it may refer to connecting fixedly or detachable or integrally; or it may refer to connecting mechanically or electrically, or communicating with each other; or it may refer to connecting directly, or connecting indirectly through an intermediate medium; or it may refer to communicating internally or interacting between two components. For those skilled in the art, the specific meanings of the above terms in this disclosure can be understood based on specific circumstances.

In addition, it is understood that, for the convenience of description, the dimensions of components shown in the attached drawings do not necessarily follow the actual proportional relationship. For example, the thickness or width of certain layers may be exaggerated relative to other layers. The techniques, methods, and devices known to those skilled in the relevant field may not be discussed in detail, but in the case of applying these techniques, methods, and devices, these techniques, methods, and devices should be considered as a part of this disclosure.

With the development of semiconductor technology, the size of devices is becoming smaller, but currently it is difficult to further reduce the size in the plane direction. Therefore, as mentioned earlier, in order to improve the integration density of memory cells, this disclosure turns to three-dimensional (3D) stacking technology and proposes a novel NOR memory device structure that is easy to be stacked vertically, which can effectively reduce the area of a single memory cell and meet the market's requirements for large capacity and small size NOR memory.

The following will provide a more detailed explanation of the novel structure and its manufacturing method disclosed herein, in conjunction with the accompanying drawings. In this disclosure, in some embodiments, the memory device may include one or more memory transistors stacked in a vertical direction. In other embodiments, the memory device may include multiple groups of vertically stacked memory transistors arranged in an array on a horizontal plane, which can also be referred to as a memory array, typically manufactured in a same chip. Usually, in addition to the memory array, the memory may also include peripheral circuits for reading/writing to the memory array, which may be manufactured in a chip same as or different from that including the memory array.

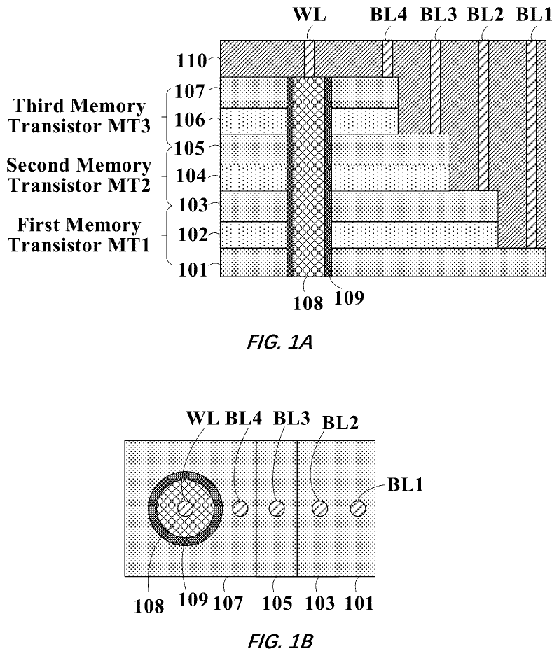

FIG. 1A shows an exemplary structure of a NOR memory device according to at least one embodiment of the present disclosure in a cross-sectional view, and FIG. 1B shows a top view of the NOR memory device in FIG. 1A in the case of removing its interlayer dielectric (ILD) layer 110.

In this disclosure, the memory device is typically provided on a substrate, with a horizontal plane referring to a surface parallel to or about parallel to the main surface of the substrate and a vertical direction referring to a direction perpendicular to or about perpendicular to the main surface of the substrate. FIG. 1A which is a cross-sectional view shows the stack structure of the memory device in the vertical direction. Those skilled in the art may understand that there are no limitations on the substrate used for manufacturing in this disclosure, which can be various substrates, such as a single crystal silicon wafer, a SOC substrate, etc., and in some cases, the substrate may be removed after the memory device is manufactured. Therefore, for clarity, the substrate has been omitted in some of the accompanying drawings of this disclosure. In some embodiments, there may also be an insulation layer between the substrate and the memory device to isolate the impact of the substrate on the memory device.

In some embodiments, as shown in FIG. 1A which shows the cross-sectional view, the NOR memory device may include three vertically stacked memory transistors (i.e., the first to third memory transistors MT1-MT3). In one implementation, each memory transistor can be used as a memory cell to store 1 bit information. In another implementation, each memory transistor can also be used to store more than 1 bit information.

Specifically, as shown in FIG. 1A, the NOR memory device comprises source/drain contact layers and isolation layers alternately stacked in the vertical direction, which are a first source/drain contact layer 101, a first isolation layer 102, a second source/drain contact layer 103, a second isolation layer 104, a third source/drain contact layer 105, a third isolation layer 106, and a fourth source/drain contact layer 107, disposed from bottom to top. The number of source/drain contact layers and isolation layers is only for illustrative purposes and is not a limitation on the scope of protection disclosed in this disclosure.

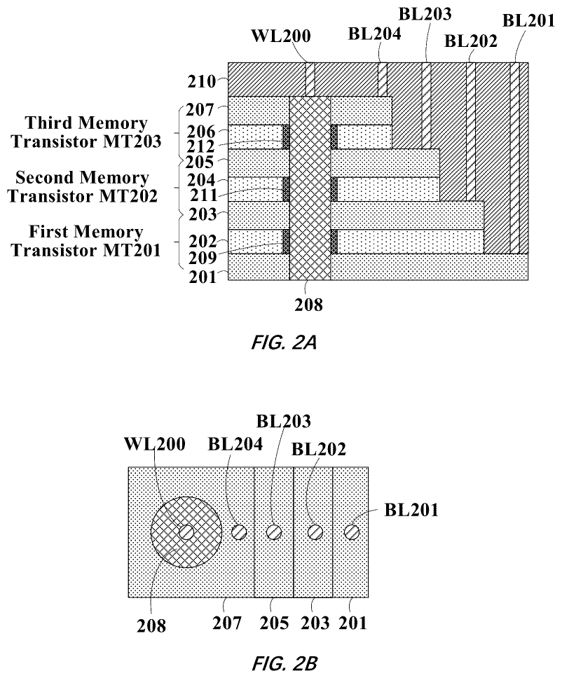

As shown in FIGS. 1A and 1B, the NOR memory device further comprises a gate structure 108 vertically extending through the respective source/drain contact layers and isolation layers, and a semiconductor layer 109 covering the periphery of the gate structure 108. These source/drain contact layers and isolation layers surround the vertically extended gate structure 108 and semiconductor layer 109, and are arranged along the direction in which the gate structure 108 extends. The semiconductor layer 109 constructs an active area for each memory transistor, including a channel area, a source area, and a drain area. Each source/drain contact layer is used to lead out the source/drain of each memory transistor to connect its respective bit/source line, thereby forming three memory transistors arranged in the vertical direction (i.e. their source-drain currents flow in the vertical direction). In the embodiments shown in FIGS. 1A and 1B, the semiconductor layers 109 present between the respective isolation layers and the gate structure 108 are continuous with each other, and are located between the sidewall of the gate structure 108 and the respective source/drain contact layers and isolation layers. In other embodiments, the semiconductor layers 109 present between the respective isolation layers and the gate structure 108 may be spaced apart from each other and only located between the sidewall of the gate structure 108 and the respective isolation layers, as will be detailed later in conjunction with FIGS. 2A and 2B as an example.

Although only one pattern is used in FIGS. 1A and 1B to represent the gate structure 108 used as the gate of the memory transistor, the gate structure 108 may be composed of multiple layers, at least including a functional layer for storing information and a conductive layer for applying voltage. For example, in some embodiments, the gate structure 108 may sequentially include a gate oxide layer, a charge capture layer, an isolation layer, and a gate metal layer from the outside to the inside. Those skilled in the art may understand that the gate structure 108 is not limited to this, but may be set accordingly according to the type of memory transistor. In the plan view of FIG. 1B, the cross-sectional shape of the gate structure 108 may be circular, that is, the gate structure 108 is cylindrical; but this is just an example, and there is no limitation on this in this disclosed embodiment. The cross-section of the gate structure 108 may be of any shape. Please note that the shape of the semiconductor layer 109 located between the gate structure 108 and the respective isolation layers shown in the plan view of FIG. 1B is only exemplary, and this disclosure is not limited to this.

In some embodiments, as shown in FIGS. 1A and 1B, the gate metal layer in the gate structure 108 may be connected to a word line (WL) on an upper layer by a contact in a interlayer dielectric layer (ILD) 110 located above the gate structure, and the source/drain contact layers may be respectively connected to bit/source lines BL1-BL4 on an upper layer by their respective corresponding contacts arranged in a stepped manner in the ILD 110. Please note that the word line and bit/source lines may be located in one or more metal layers above the ILD 110, which may be in the same or different metal layers. For clarity, the upper metal layer(s) is omitted in the drawings, and the contacts in the ILD 110 are used to refer to the word line or bit/source lines to be connected finally. Although not shown in the drawings, in some embodiments, in actual manufacturing, there may be other components on the steps for forming the stepped contacts for the bit/source lines BL1-BL4, such as spacers, metal silicides and the like, which will be described later when discussing the manufacturing process.

In the embodiments shown in FIGS. 1A and 1B, two source/drain contact layers located immediately above and below each isolation layer are respectively connected to two bit/source lines, and form a corresponding memory transistor together with the gate structure 108 and the semiconductor layer 109 located between the corresponding isolation layer and the gate structure 108. For example, the first memory transistor MT1 includes: the first source/drain contact layer 101 connected to the bit/source line BL1, the second source/drain contact layer 103 connected to the bit/source line BL2, the gate structure 108, and the portion of the semiconductor layer 109 located at least between the gate structure 108 and the first isolation layer 102. The second memory transistor MT2 includes: the second source/drain contact layer 103 connected to the bit/source line BL2, the third source/drain contact layer 105 connected to the bit/source line BL3, the gate structure 108, and the portion of the semiconductor layer 109 located at least between the gate structure 108 and the second isolation layer 104. The third memory transistor MT3 includes: the third source/drain contact layer 105 connected to the bit/source line BL3, the fourth source/drain contact layer 107 connected to the bit/source line BL4, the gate structure 108, and the portion of the semiconductor layer 109 located at least between the gate structure 108 and the third isolation layer 106. That is to say, the two adjacent memory transistors in the vertical direction share a source/drain contact layer and also share a bit/source line.

Due to the fact that the source/drain areas at the upper and lower ends of the memory transistor are structurally identical, each of the source/drain areas at the upper and lower ends of the memory transistor may serve as a source area or a drain area, and thus each of the source/drain contact layers as the upper and lower layers may serve as a source contact or a drain contact. Therefore, each of the bit/source lines BL1-BL4 connected to the respective source/drain contact layers may also serve as a bit line (BL) or a source line (SL) of the memory transistor. In addition, every adjacent two memory transistors share one bit/source line, thus in some cases, the bit/source line of one of the memory transistors may simultaneously serve as the bit/source line of the adjacent memory transistors. That is to say, the bit lines and source lines of the respective memory transistors are not fixed, but are determined based on voltages applied separately during actual operation. For the sake of simplicity and convenience in this disclosure, there is no distinction between bit lines and source lines in the accompanying drawings. Instead, all metal lines connected to the source/drain areas are collectively referred to as bit/source lines BLs. In practical use, each of the bit/source lines BLs (BL1-BL4) in any attached drawing may be used as either the source line or the bit line. That is, when the bit/source line BL in any of the attached drawings is applied with the source voltage required for the memory transistor, the corresponding metal line constructs the source line of the memory transistor, and at this time, the metal line may be referred to as the source line. When the bit/source line BL is applied with the drain voltage required for the memory transistor, the corresponding metal line constructs the bit line of the memory transistor, and at this time, the metal line may be referred to as the bit line.

FIGS. 1A and 1B only illustrate the case of three stacked memory transistors as examples, but more or fewer memory transistors may be stacked as needed, which share the same vertically extended gate structure, and are achieved by changing the number of source/drain contact layers and isolation layers alternately stacked in the vertical direction and ensuring the presence of semiconductor layer between each isolation layer and the gate structure. For example, in some embodiments, only one memory transistor may be stacked in the vertical direction, which includes two source/drain contact layers and one isolation layer alternately stacked in the vertical direction. For example, in other embodiments, h memory transistors (h is a natural number greater than 1) may be stacked in the vertical direction. In this case, the NOR memory device may include (h+1) source/drain contact layers and h isolation layers alternately stacked in the vertical direction, wherein a semiconductor layer exists between each of the isolation layers and the gate structure, and the (h+1) source/drain contact layers are respectively connected to (h+1) bit/source lines. Two of the source/drain contact layers located immediately above and below each of the isolation layers, the gate structure, and the semiconductor layer located between the corresponding isolation layer and the gate structure form a corresponding memory transistor, thus the h vertically stacked memory transistors are formed.

In some embodiments, the source/drain contact layer used in this disclosure may be made of a material containing metal (such as tungsten) or polysilicon, or the source/drain contact layer may be made of metal or polysilicon. In some embodiments, the isolation layer used in this disclosure may be made of a material containing silicon oxide or silicon nitride, or the isolation layer may be made of silicon oxide or silicon nitride. In some embodiments, the semiconductor layer used in this disclosure may be made of a material containing polysilicon, or the semiconductor layer may be made of polysilicon. In some embodiments, any of the metal lines, such as word lines, bit/source lines and the like, and the corresponding contacts, used in this disclosure, may be made of a material containing tungsten, or any of the metal lines, such as word lines, bit/source lines and the like, and the corresponding contacts may be made of tungsten. A specific example of the manufacturing process for the NOR memory device disclosed herein will be described in detail later in conjunction with the accompanying drawings.

Those skilled in the art may understand that the NOR memory device disclosed herein is not limited to the specific structures described in combination with FIGS. 1A and 1B. For example, in some other embodiments, an insulation layer may be set between adjacent memory transistors in the vertical direction, that is, an insulation layer may be set between the source/drain contact layers of adjacent memory transistors, so that each memory transistor has two independent source/drain contact layers without sharing the source/drain contact layer. Therefore, as in conventional NOR memory devices, a separate bit line and a separate source line for each memory transistor are led out. However, compared to the structure of setting the insulation layer, the NOR memory device according to FIGS. 1A and 1B disclosed herein has a simpler structure, is easier to manufacture, and reduces the number of required bit lines and source lines, thereby further improving the integration density.

FIG. 2A illustrates an exemplary structure of a NOR memory device according to at least one embodiment of the present disclosure in a cross-sectional view, and FIG. 2B shows a top view of the NOR memory device in FIG. 2A after removing ILD 210.

The main difference between the exemplary structures of NOR memory devices shown in FIGS. 2A-2B and FIGS. 1A-1B lies in the arrangement of semiconductor layers in the respective memory transistors. Specifically, in the embodiment shown in FIGS. 1A-1B, the semiconductor layers present between the respective isolation layers and the gate structure in the vertically stacked memory transistors are continuous with each other, while in the embodiment shown in FIGS. 2A-2B, the semiconductor layers present between the respective isolation layers and the gate structure in the vertically stacked memory transistors may be spaced apart from each other.

For example, as shown in FIG. 2A, the semiconductor layer 209 in the first memory transistor MT201, the semiconductor layer 211 in the second memory transistor MT202, and the semiconductor layer 212 in the third memory transistor MT203 all surround the gate structure 208, forming their respective active areas, but they are separated from each other by a source/drain contact layer. Due to the semiconductor layers shown in FIG. 2A being located below the source/drain contact layers, unlike the top view in FIG. 1B, the semiconductor layers cannot be seen in the top view of FIG. 2B.

For example, in the embodiment shown in FIG. 2A, the gate structure 208 shared by the memory transistors contacts the sidewalls of the respective source/drain contact layers 201, 203, 205, and 207. The sidewall of each isolation layer 202, 204, or 206 is recessed in the horizontal direction relative to the sidewalls of its respective adjacent source/drain contact layers located immediately above and below. Each semiconductor layer 209, 211, or 212 contacts the gate structure 208 and the sidewall of its respective isolation layer 202, 204, or 206, and is located in the recessed part from the sidewall of the corresponding isolation layer 202, 204, or 206 relative to the sidewalls of the source/drain contact layers in the horizontal direction.

Compared to the example shown in FIGS. 1A-1B where the semiconductor layers are continuous with each other, spacing the semiconductor layers in the vertically stacked memory transistors from each other can reduce mutual influence between the memory transistors, for example, avoid interference caused by channel leakage in other memory transistors that share the same gate structure or the like.

Please note that, except for the arrangement of the semiconductor layers discussed above, the specific construction of the NOR memory device shown in FIGS. 2A and 2B of this disclosure may refer to the accompanying drawings and related discussions of other embodiments of this disclosure, for example, the content of the embodiment shown in FIGS. 1A and 1B, which will not be repeated here. Those skilled in the art understand that this disclosure is not limited to the construction of NOR memory devices mentioned above, and any other suitable construction may be adopted.

Taking a single group of vertically stacked memory transistors as an example, the NOR memory device according to the present disclosure has been discussed in detail above. In some embodiments, usually multiple groups of vertically stacked memory transistors are arranged in an array on a horizontal plane to form a three-dimensional memory array. Below, structures, circuits, and manufacturing processes of some exemplary memory arrays arranged in 3D will be discussed, in conjunction with the accompanying drawings.

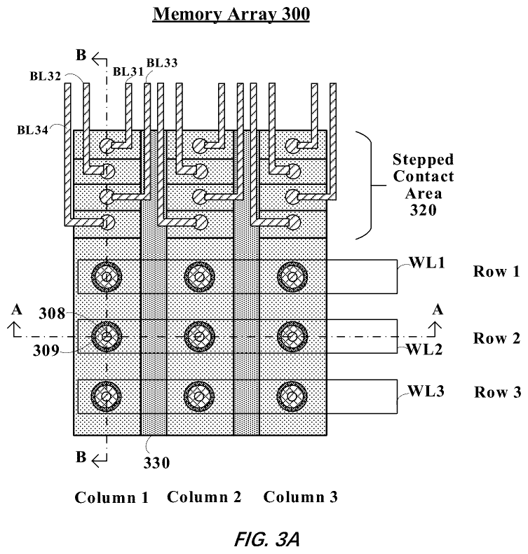

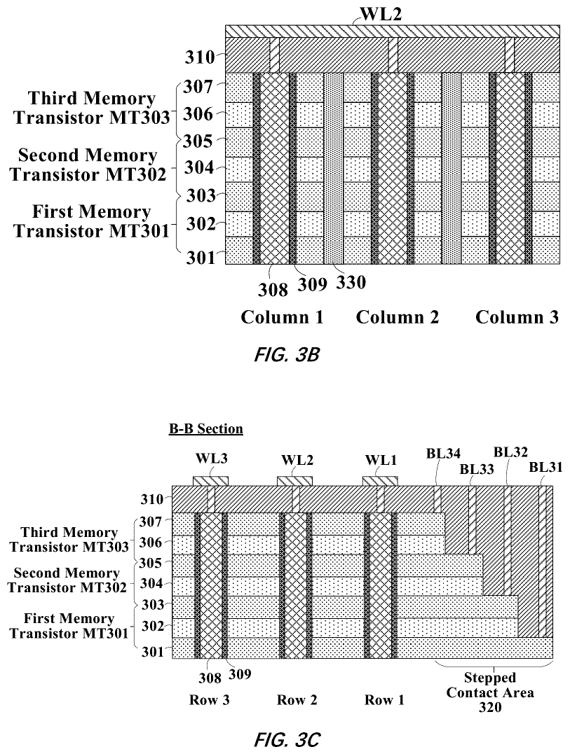

FIG. 3A shows a schematic plan view of a NOR memory array according to at least one embodiment of the present disclosure, FIG. 3B shows a schematic cross-sectional view taken along the dashed line A-A as shown in FIG. 3A, and FIG. 3C shows a schematic cross-sectional view taken along the dashed line B-B as shown in FIG. 3A.

As shown in FIG. 3A, the NOR memory array 300 may include multiple gate structures 308 arranged in 3 rows×3 columns on the horizontal plane, wherein the gate structures 308 may have a construction as described in any of the aforementioned embodiments, extending vertically through alternately stacked source/drain contact layers and isolation layers, serving as the gate for one or more vertically stacked memory transistors. The specific construction of each memory transistor may adopt that described in the embodiment shown in FIGS. 1A-1B, although this disclosure is not limited to this. Please note that in the plan view of FIG. 3A, in order to more clearly show the connection relationship between the gate structures of respective rows and the word lines WL1-WL3, the word lines WL1-WL3 are drawn as blank rectangular boxes so as to reveal the gate structures and their contacts connecting to the word lines located below the word lines.

Those skilled in the art may understand that the number of rows and columns shown in this disclosure is only illustrative. In practice, any n*m array may be made as needed, where n and m are natural numbers greater than 1. Those skilled in the art may understand that adopting an n*m layout is only one of the ways to implement the technical solution of the disclosed embodiments, and the embodiments of the present disclosure are not limited to this. In addition, the terms “n rows” or “m columns” referred to in all embodiments of this disclosure only refer to the arrangement of multiple gate structures in an array, rather than limiting these gate structures to be exactly arranged in a neat array as shown in the drawings. The rows and columns in an array are not determined by the positions of the gate structures, but by the connection relationships for the memory transistors formed by the respective gate structures (such as the connection relationships with the word lines, bit/source lines, etc.). That is to say, the “column” referred to throughout the various embodiments disclosed in this disclosure may be a completely virtual concept, which may be gate structures arranged in an approximately horizontal or vertical direction on a horizontal plane, or even gate structures extended in an arc or curve shape, and which may be based on artificial setting/partitioning. Similarly, the term “row” referred to throughout the various embodiments disclosed herein may be a completely virtual concept, which may be gate structures arranged in an approximately horizontal or vertical direction on a horizontal plane, or even gate structures extended in an arc or curved shape, and which may be based on artificial settings/partitioning. The memory array referred to throughout the various embodiments of this disclosure includes the gate structures in the n*m array, which does not limit the number of gate structures contained in each row to be the same, and does not limit the number of gate structures contained in each column to be the same.

The structure shown in FIG. 3A includes three rows of gate structures 308, and the number of gate structures 308 included in each of the three rows is equal, that is, each row includes three gate structures 308; but this is just an example, and not a limitation on the scope of protection of the disclosed technical solution. Those skilled in the art may understand that the number of gate structures 308 included in each row may be the same or different. Similarly, the structure shown in FIG. 3A includes three columns of gate structures 308, and the number of gate structures 308 included in each of the three columns is equal, that is, each column includes three gate structures 308; but this is just an example, and not a limitation on the scope of protection of the disclosed technical solution. Those skilled in the art may understand that the number of gate structures 308 included in each column may be the same or different. Apparently, shown in FIG. 3A is a 3*3 array, i.e., n=3 and m=3; but those skilled in the art may understand that n and m may be any number, which are not limited in the embodiments of the present disclosure. In this disclosure, the gate structure 308 may have a structure as shown in FIGS. 1A-1B, serving as a gate shared by a group of memory transistors stacked vertically. The group of memory transistors may include h (h is a natural number greater than 1) memory transistors, and a memory transistor refers to a transistor having the function of storing data. As a result, the memory transistors may form a three-dimensional memory array of n*m*h. Those skilled in the art understand that the disclosed embodiments do not limit the numbers of vertically stacked memory transistors in the respective groups, which may be the same or different. Due to the ability to stack multiple memory transistors vertically, i.e. multiple memory transistors occupying the footprint of only one memory transistor, the integration density of the memory array can be greatly improved.

In some embodiments, as shown in FIGS. 3B and 3C which show the cross-sectional views, similar to those described earlier in conjunction with FIGS. 1A-1B, each gate structure 308 may form a group of vertically stacked memory transistors (hereinafter also referred to as a memory transistor group), that is, each gate structure 308 may form three vertically stacked memory transistors (i.e., the first to third memory transistors MT301-MT303) together with its surrounding source/drain contact layers 301, 303, 305, 307, and semiconductor layer 309. In one implementation, each memory transistor may be used as a memory cell to store 1 bit information. As shown in FIGS. 3B and 3C, exemplary examples are shown that each memory transistor group includes three vertically stacked memory transistors; but this is only an example and not a limitation on the scope of protection of the disclosed technical solution. Those skilled in the art may understand that the number of memory transistors included in each memory transistor group may be the same or different. For example, one or more memory transistor groups therein may include only 2 memory transistors (i.e. h=2 in some memory transistor groups), while other memory transistor groups may include any number of memory transistors (e.g. h=3 in another memory transistor group). For example, one or more memory transistor groups therein may include four memory transistors (i.e. h=4 in some memory transistor groups), while other memory transistor groups may include any number of memory transistors (e.g. h=3 in another memory transistor group).

As shown in FIGS. 3B and 3C, each memory transistor group may adopt the structure described in the embodiments shown in FIGS. 1A-1B, although this disclosure is not limited to this. In FIGS. 3B and 3C, in order to better illustrate the connection relationship between the gate structures and the word lines, metal lines are drawn above ILD 310 as word lines. However, please note that this disclosure is not limited to this. In some embodiments, the word lines WL of the respective rows may be arbitrarily distributed in one or more metal layers above the ILD 310. Although not shown in FIGS. 3B and 3C, please note that the bit/source lines BL used for the source/drain contact layers in the respective columns and stack levels may also be arbitrarily distributed in one or more metal layers above the ILD 310.

In addition, in the example shown in FIGS. 3A and 3C, three memory transistor groups in the same column share four vertically stacked source/drain contact layers, namely the first source/drain contact layer 301, the second source/drain contact layer 303, the third source/drain contact layer 305, and the fourth source/drain contact layer 307; that is to say, there are (h+1) source/drain contact layers in the same column, and these (h+1) source/drain contact layers respectively extend along the direction of the column. All memory transistors in the column use these (h+1) source/drain contact layers as their own source/drain contact layers. As shown in FIGS. 3A and 3C, the source/drain contact layers of all memory transistors located at the same layer in the vertical direction (also referred as the same vertical layer/level) are respectively continuous. Therefore, only one contact may be used to achieve the electrical connection to the source/drain areas of all memory transistors at the same layer (also referred as the same stack layer) in the same column, which further improves the integration density. The same layer may refer to, as shown in FIG. 3B, the memory transistors at the bottom of the first, second, and third columns in the vertical direction, which are referred to as being at the same layer; correspondingly, the memory transistors at the top of the first, second, and third columns in the vertical direction are also referred as being at the same layer; the memory transistors in the middle of the first, second, and third columns in the vertical direction are also referred as being at the same layer.

For example, as shown in FIGS. 3A and 3C, a stepped contact area 320 may be fabricated at the end of each column, where the stepped contact area 320 is provided with contacts for connecting the respective source/drain contact layers. The contacts are used to respectively lead out these four source/drain contact layers to electrically connect four metal lines (i.e. bit/source lines) BL31-BL34. Please note that the present disclosed embodiments are not limited to the implementation shown in FIGS. 3A and 3C for leading out each source/drain contact layer, but may adopt various other implementations. For example, in some possible implementations, more than one contact for connecting to the corresponding metal line may be formed on one or more source/drain contact layers in the stepped contact area 320, in order to achieve better electrical connection. In other possible implementations, stepped contact areas may be fabricated at both ends of each column, where the stepped contact areas at both ends are provided with contacts for connecting the respective source/drain contact layers to their corresponding bit/source lines, and the contacts at both ends of the same layer are electrically connected to the same bit/source line, so as to reduce resistance and achieve better electrical connection.

In the example shown in FIGS. 3A and 3C, all h memory transistors in the same column share these (h+1) source/drain contact layers. Those skilled in the art may understand that some memory transistors in the same column may share part of the source/drain contact layers, while some other memory transistors may share other source/drain contact layers or have independent source/drain contact layers. Correspondingly, the contacts may also be set based on the structure of the source/drain contact layers, and will not be repeated here.

In addition, as shown in FIGS. 3A-3C, all gate structures 308 in the same row are connected to the same word line WL1, WL2, or WL3, while the memory transistors located at the same stack layer in all memory transistor groups formed by the respective gate structures 308 in the same column share the same bit/source line, as mentioned earlier. In addition, an isolation part 330 is arranged between memory transistor groups formed by adjacent columns of the gate structures 308, to isolate the source/drain contact layers of the memory transistors in different columns, thereby separating the bit/source lines used for the memory transistors in different columns. That is to say, the source/drain contact layers located at the same vertical layer in the memory transistors formed by the gate structures of adjacent columns are isolated from each other. Therefore, according to the memory array structure disclosed herein, it is possible to uniquely locate a memory cell solely through its word line and its bit line, and one memory cell therein is one memory transistor. Therefore, the architecture of the memory array according to this disclosure is simple, greatly reducing design difficulty, and improving manufacturability. Moreover, due to the presence of isolation parts between the bit lines of different columns, the leakage and crosstalk on the bit lines are reduced.

Please note that although different filling patterns are used in the various drawings disclosed herein to distinguish insulation components such as vertically stacked isolation layers, isolation parts between adjacent columns, and interlayer dielectric layers and the like, in some possible embodiments, some or all of these insulation components may include the same insulation material (such as silicon oxide and/or silicon nitride), or be made of the same insulation material, which may actually be the same material layer, but may be formed in different manufacturing process steps or have different functions. Similarly, although different filling patterns are used in the various drawings disclosed herein to distinguish conductive components such as contacts, word lines, bit/source lines, source/drain contact layers, contact metals, vias and the like, in some possible embodiments, some or all of these conductive components may include the same conductive material (such as tungsten) or be made of the same conductive material, which may actually be the same material layer, but with different functions, or may be formed in different manufacturing process steps.

Please note that in order to make the illustrations clear and highlight the key points, there are blank areas left between some components in the cross-sectional views of this disclosure, which does not necessarily limit these areas to be empty. In some implementations, in actual devices, all or part of these blank areas may be filled with electrical insulation materials to isolate and support these components.

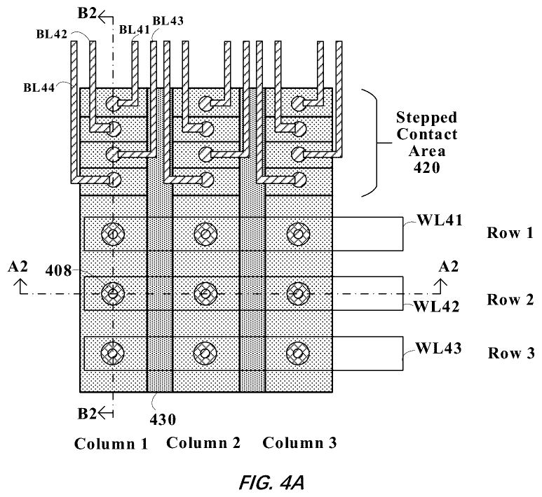

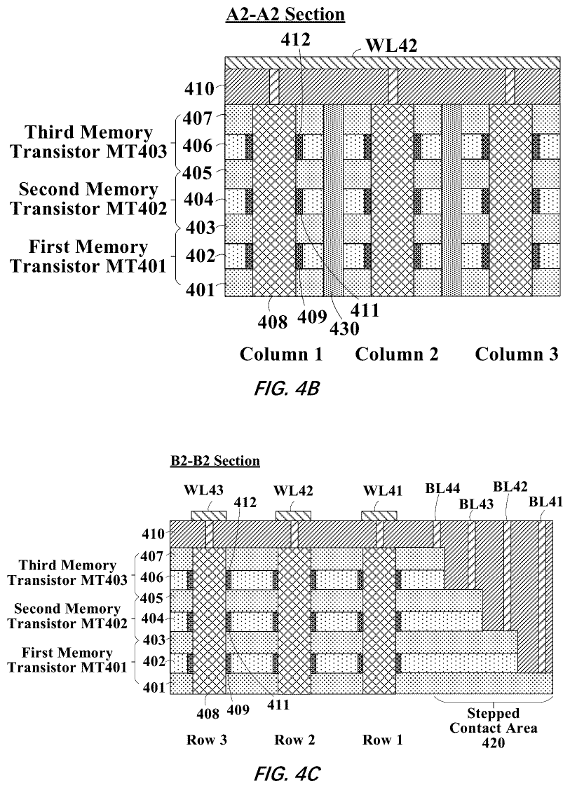

FIG. 4A shows a schematic plan view of an array composed of NOR memory devices according to at least one embodiment of the present disclosure, FIG. 4B shows a schematic cross-sectional view taken along the dashed line A2-A2 as shown in FIG. 4A, and FIG. 4C shows a schematic cross-sectional view taken along the dashed line B2-B2 as shown in FIG. 4A.

The main difference between the exemplary memory array shown in FIGS. 4A-4C and the exemplary memory array shown in FIGS. 3A-3C lies in the arrangement of semiconductor layers in the respective memory transistors. Specifically, in the embodiment shown in FIGS. 3A-3C, each memory transistor group may adopt a structure as described in the embodiment shown in FIGS. 1A-1B earlier, that is, in the vertically stacked memory transistors, the semiconductor layers present between the respective isolation layers and the gate structure are continuous with each other; while in the embodiment shown in FIGS. 4A-4C, each memory transistor group may adopt a structure as described in the embodiment shown in FIGS. 2A-2B earlier, that is, in the vertically stacked memory transistors, the semiconductor layers present between the respective isolation layers and the gate structure may be spaced apart from each other, such as the semiconductor layers 409, 411, and 412 spaced apart by the source/drain contact layers shown in FIGS. 4A-4C.

Please note that the specific construction of each memory transistor group in the memory array of this embodiment is not limited to the structure described in the embodiment shown in FIGS. 2A-2B, and any other suitable construction may be used as long as it separates the semiconductor layers in the respective vertically stacked memory transistors from each other.

Please note that, except for the arrangement of the semiconductor layers discussed above, the specific construction of the memory array shown in FIGS. 4A-4C of this disclosure may refer to the accompanying drawings and related discussions of other embodiments of this disclosure, such as the content in the embodiment shown in FIGS. 3A-3C, which will not be repeated here. Those skilled in the art may understand that this disclosure is not limited to the construction of the NOR memory array mentioned above, and any other suitable construction may be adopted.

In order to arrange the memory array more closely and further improve the array density, part of the gate structures in column 1 of FIG. 3A or FIG. 4A may be moved a certain distance in the row direction, so as to be spaced from adjacent gate structures at certain spacings in both the column and row directions. That is, the spacing between adjacent gate structures is a slanted distance, which can reduce the spacings in the column and/or row directions and further reduce the vertical and/or horizontal dimensions of the entire memory array. For example, at least one column of the gate structures may include i sub-columns of the gate structures, where i is a natural number greater than 1; wherein the gate structures of at least two adjacent sub-columns are spaced in the column direction. That is to say, the adjacent gate structures in the row direction do not completely overlap in the column direction as shown in FIG. 3A or FIG. 4A, but are staggered by a certain distance. That is to say, an improved arrangement of memory arrays may be proposed, which can reduce the area occupied by the entire memory array in the horizontal plane and further increase the array density. This arrangement is particularly useful in some situations. For example, in some embodiments, although smaller size processes can be used to produce memory arrays, the size of the gate structure (such as the diameter of the gate circular hole) cannot be further reduced. For example, in some embodiments, the minimum size (including its width (diameter of the circular holes) and spacing) of the gate structure may reach around 100 nm and cannot be further reduced, while smaller size processes (such as 40 nm or 28 nm process) can be used to fabricate memory arrays. In other words, the minimum size (including its width and spacing) of the metal line (word line WL) connecting the gate structure can reach around 40 nm or 28 nm. At this point, the above staggered arrangement can minimize the area required for the gate structure array.

Below, this improved implementation will be presented more clearly in conjunction with the attached drawings.

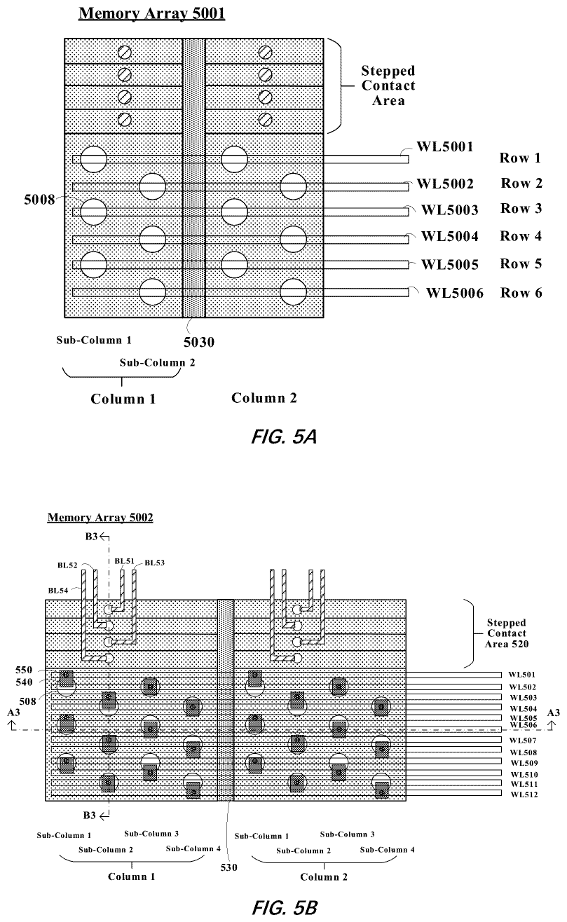

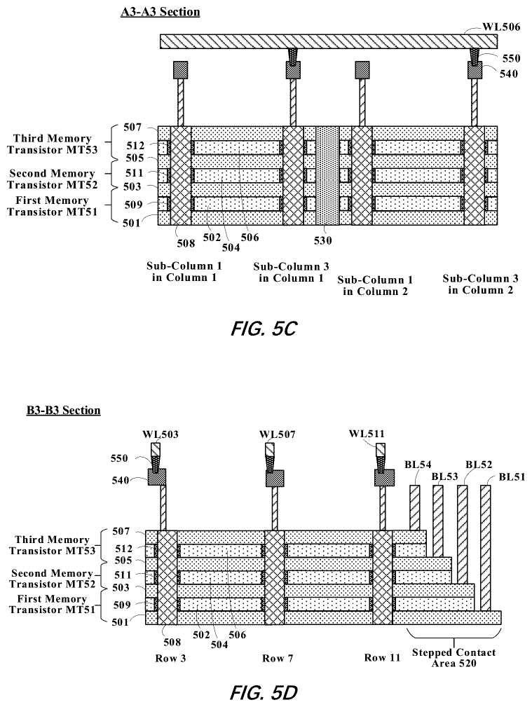

FIG. 5A shows an exemplary schematic plan view of an array composed of NOR memory devices according to at least one embodiment of the present disclosure.

Please note that FIG. 5A mainly intends to illustrate the arrangement of the gate structures in each column on the horizontal plane. Therefore, for clarity, FIG. 5A does not show the bit/source lines in the stepped contact area, and only uses a blank circle to represent the gate structures 5008. In addition, the contacts between the gate structures 5008 and the word lines are not shown, and the overlaps of the blank gate structures and the blank word lines indicate their respective connections. The memory transistor groups formed by the respective gate structures 5008 shown in FIG. 5A may adopt the specific constructions as those described in the previous embodiments in combination with FIGS. 1A-1B, FIGS. 2A-2B, FIGS. 3A-3C, or FIGS. 4A-4C, or combinations of various constructions in these embodiments, or any other suitable constructions, which will not be repeated here. Therefore, the cross-sectional views corresponding to FIG. 5A are not shown, which may refer to the constructions of the cross-sectional views described in the aforementioned embodiments.

As shown in FIG. 5A, the NOR memory array 5001 includes multiple gate structures arranged in 6 rows×2 columns on a horizontal plane. Those skilled in the art may understand that, as mentioned earlier regarding FIG. 3A, the number of rows and columns, as well as the number of gate structures included in each row/column, in the disclosed drawings are only exemplary. In practice, any n*m array may be made as needed, where n and m are natural numbers greater than 1, and the number of gate structures included in each row/column may also be arranged as needed.

As shown in FIG. 5A, in some embodiments, two or more adjacent sub-columns may be set in one column, and each sub-column may include two or more gate structures; wherein, the gate structures of adjacent sub-columns are staggered in the row direction. In some embodiments, the gate structures in each sub-column are arranged along the column direction, such as aligned in the column direction. However, this disclosed embodiment is not limited to this, and may also be arranged in other ways (such as by a certain curve) in the column direction. Shown in FIG. 5A is an exemplary structure where one column includes two sub-columns; however, those skilled in the art may understand that this exemplary explanation is not a limitation to the embodiments of the present disclosure. On the basis of ensuring the possibility of technological implementation, any number of sub-columns may be arranged in one column, and for example, three or more sub-columns may be arranged in one column.

In one implementation, in order to arrange the memory array more closely, each of the gate structures 5008 in the two sub-columns of FIG. 5A may have the same distance from each of its adjacent gate structures 5008 in the column direction, and for example, this distance may be the minimum column spacing required by the process or design. In one implementation, each gate structure 5008 in the two sub-columns of FIG. 5A may have the same distance from each of its adjacent gate structures 5008 in the row direction, and for example, this distance may be the minimum row spacing required by the process or design. In the above embodiments, the minimum row spacing may be the same as or different from the minimum column spacing. In one possible implementation, in order to arrange the memory array more closely, each gate structure 5008 may have the same distance (such as the minimum spacing) from each of its adjacent gate structures 5008 in the column or row direction. That is to say, the gate structures 5008 may be arranged in the most compact hexagonal pattern, in order to further improve the array density.

As shown in FIG. 5A, since the size of the metal line (word line WL) connecting the gate structure 5008 may be smaller than the size of the gate structure 5008, the gate structures 5008 in these two sub-columns may be connected to the corresponding word lines WL respectively, and the two word lines WL may extend side by side without any contact.

In addition, in some embodiments, the number of sub-columns in each column may be appropriately designed based on the ratio of the minimum size of the gate structure to the minimum size of the word line WL, in order to better reduce the size of the entire memory array and improve integration density. For example, in some embodiments, the minimum size of the gate structure may be exemplarily around 100 nm, where the minimum size may refer to the width of the gate structure or the spacing between the gate structures, and the width of the gate structure may be the diameter of the circular hole. The minimum size of the metal line (word line WL) connecting the gate structures may be exemplarily around 28 nm, which includes the width of the metal line and the spacing between adjacent metal lines. It can be seen that the ratio of the minimum size of the gate structure to the minimum size of the word line WL in the above example may be around 4:1. In the above example, the minimum sizes of the gate structure and the word line WL may determine that up to 4 sub-columns may be staggered in the same column, as shown in FIG. 5B below. Apparently, the minimum size of the gate structure and the minimum size of the word line WL mentioned above are only examples and are not limitations on the disclosed embodiments.

FIG. 5B shows another exemplary schematic plan view of an array composed of NOR memory devices according to at least one embodiment of the present disclosure, FIG. 5C shows a schematic cross-sectional view taken along the dashed line A3-A3 in FIG. 5B, and FIG. 5D shows a schematic cross-sectional view taken along the dashed line B3-B3 in FIG. 5B.

In FIG. 5B, exemplarily shown is that the gate structures 508 of four sub-columns may be staggered and arranged in the same column. For example, the structure of the gate structure 508 corresponding to a vertically stacked memory transistor group may refer to the accompanying drawings of other embodiments disclosed herein. The construction of the gate structure 508 shown in FIG. 5B may refer to, for example, the gate structure in FIGS. 1A-1B, FIGS. 2A-2B, FIGS. 3A-3C, or FIGS. 4A-4C, and may also be any other shape or structure of the gate structure.

As shown in FIG. 5B, due to the presence of two gate structures 508 placed side by side in the row direction in one column, it is difficult to stagger the connections by using the metal layer above the gate structure 508 as the word lines WL, as shown in FIGS. 3A-3C or FIGS. 4A-4C. Therefore, an additional metal layer may be added, as the word lines WL, above the metal layer in contact with and on the gate structures 508 as shown in FIGS. 3A-3C or 4A-4C. In one possible implementation, as shown in FIG. 5B which shows the plan view and the subsequent FIGS. 5C and 5D which show the corresponding cross-sectional views, a contact metal 540 is formed above each gate structure 508 to widen the connectable area of the gate structure 508, and then a via 550 is formed on the contact metal 540 and electrically contacts the contact metal 540, and a metal line (word line WL) is formed on the upper layer of the via 550 to electrically contact the via 550. As needed, a connection structure similar to the contact metal 540 and the via 550 in FIGS. 5B-5D may also be formed above the gate structures shown in the previous embodiments, which is not limited by the embodiments of the present disclosure. Some or all of the word lines WL in the various embodiments disclosed herein may also use other wiring implementation as needed, rather than being limited to the straight wiring implementation shown in the accompanying drawings. Moreover, the respective word lines may not be limited to being distributed in a same metal layer, but may be distributed in multiple metal layers as needed.

In one possible implementation, in order to arrange the memory array more closely, each gate structure 508 in the four sub-columns of FIG. 5B may have the same distance (e.g. minimum spacing) from each of its adjacent gate structures 508 in the column or row direction. That is to say, the gate structures 508 in each column may be arranged in the most compact hexagonal pattern, in order to further improve the array density.

In one possible implementation, as shown in FIGS. 5C and 5D which show the cross-sectional views, the memory transistor group formed by each gate structure 508 in the memory array 5002 may include three vertically stacked memory transistors (i.e., the first to third memory transistors MT51-MT53), which may adopt the specific construction of the memory transistor group in the embodiments shown in FIGS. 2A-2B or FIGS. 4B-4C earlier. The main difference between the cross-sectional views of FIGS. 5C and 5D and the cross-sectional views of FIGS. 4B and 4C in the structure of the memory transistor group is that, as shown in the A3-A3 section of FIG. 5C, the gate structures 508 of multiple sub-columns in the same column may exist at the same horizontal position, and the source/drain contact layers of all sub-columns located at the same stack layer are continuous; in addition, as mentioned earlier, the connection structure with the contact metal 540 and the via 550 is added above the gate structure 508 to connect to the word line WL. Other specific structures of the memory transistor group shown in the cross-sectional views of FIGS. 5C and 5D may refer to those in the embodiment described in conjunction with FIGS. 4B and 4C, and will not be repeated here.

Those skilled in the art may understand that the present disclosure is not limited to the construction of the memory transistor group mentioned above, and memory transistor groups with any other construction may also be used, such as the specific construction shown in the embodiment shown in FIGS. 1A-1B or FIGS. 3A-3C, which has the semiconductor layer continuously extending in the vertical direction.

In some embodiments, the columns separated by the isolation part 530 may be referred to as respective planes in the memory array, wherein each plane may include the memory transistor groups formed by the gate structures 508 of the corresponding column. Any number of the multiple planes (i.e. multiple columns) may be set according to actual capacity requirement. In any plane, M lines of the gate structures 508 may be placed (equivalent to setting M sub-columns), according to the layout wiring requirement, where M≥1, and N gate structures 508 may be placed in each line, where N>1. Any two gate structures 508 within a plane may not be connected to the same word line WL, while the gate structures 508 within different planes may be connected to the same word line WL through metal wiring. That is to say, any two gate structures 508 in the same column may not be connected to the same word line WL, while the gate structures 508 of different columns, which belong to the same row, may be connected to the same word line WL through metal wiring. Although the drawing only shows setting up a stepped contact area 520 at one end of the plane to connect the source/drain contact layers of the respective stack layers to their respective bit/source lines, it is also possible to set up stepped contact areas 520 at both ends of the plane to connect the two ends of the source/drain contact layer at the same stack layer together and lead them out, thereby reducing resistance.

Please note that in order to make the illustrations clear and highlight the key points, there are blank areas left between many components in the cross-sectional views of FIGS. 5C and 5D, which does not necessarily limit these areas to be empty. In some implementations, in actual devices, all or part of these blank areas may be filled with electrical insulation materials to isolate and support these components.

The following, in conjunction with FIGS. 6-9, is a detailed description of the circuit structure and corresponding read/write operations of the memory array shown in FIGS. 1A-1B, FIGS. 2A-2B, FIGS. 3A-3C, FIGS. 4A-4C, FIG. 5A, or FIGS. 5B-5D. FIGS. 6-9 are illustrated using a 3*3*3 array as an example, but please note that this disclosure is not limited to this.

FIG. 6 illustrates a schematic diagram of a memory array circuit 600 according to at least one embodiment of the present disclosure.

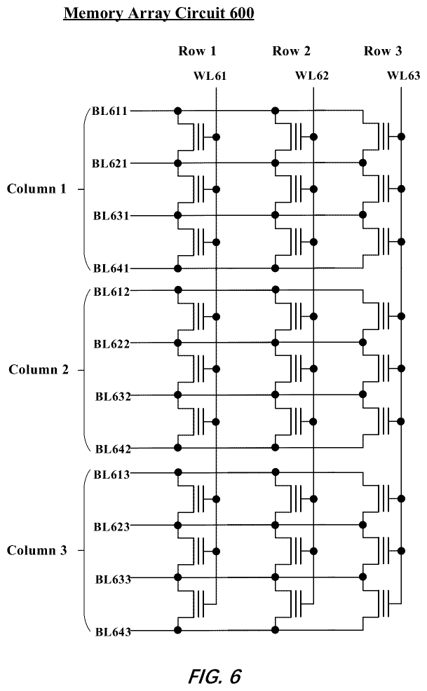

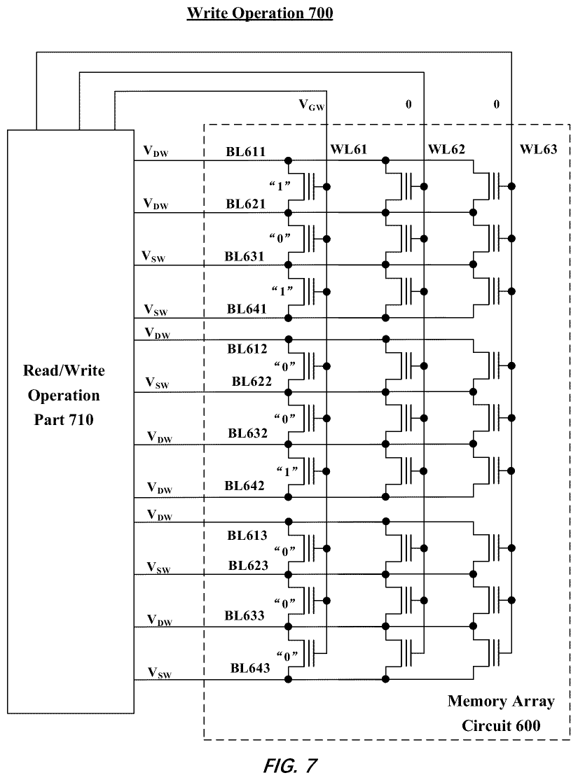

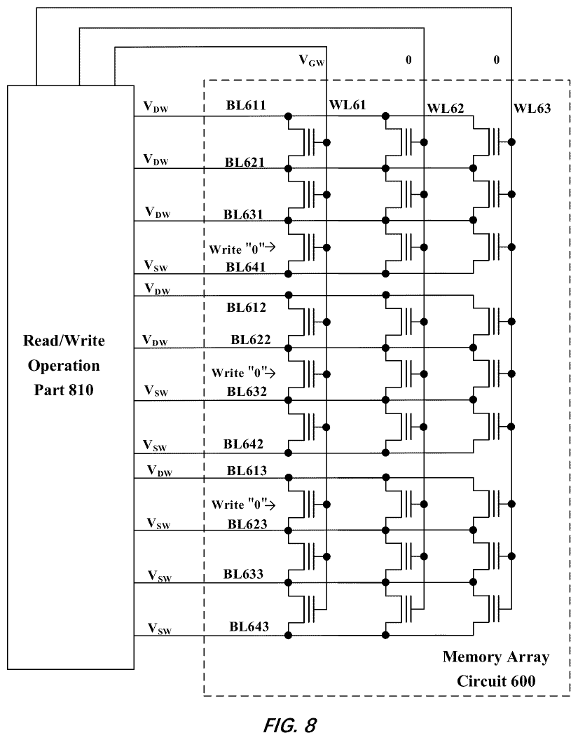

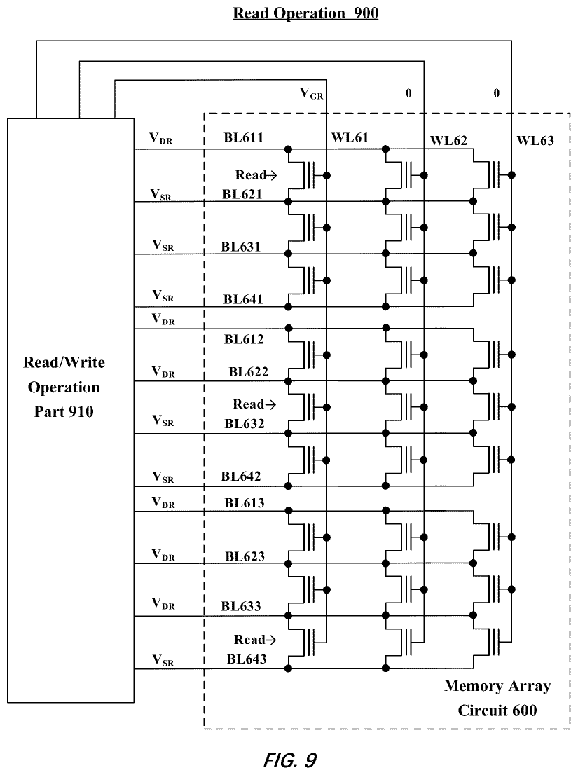

As shown in FIG. 6, the gates of memory transistors in the same row are all connected to the same word line WL61, WL62, or WL63, while all memory transistor in the same column share the respective common bit/source line BL611, BL621, BL631, BL641, or BL612, BL622, BL632, BL642, or BL613, BL623, BL633, BL643. As mentioned earlier, since the memory array in this disclosure is arranged in a three dimension manner, each memory transistor group in each column includes three vertically stacked memory transistors. Therefore, as shown in FIG. 6, each column may actually include three sub-columns arranged in the vertical direction, and the memory transistors in adjacent sub-columns in the vertical direction share a source/drain contact area. The circuit structure shown in FIG. 6 is only an example, and the embodiments of the present disclosure do not limit the write operation of FIG. 7 or FIG. 8, and the read operation of FIG. 9 can only be applied to the circuit structure shown in FIG. 6.

FIG. 7 shows an example of a write operation performed on the memory array shown in FIG. 6 by a NOR memory according to at least one embodiment of the present disclosure. FIG. 8 shows another example of a write operation performed on the memory array shown in FIG. 6 by a NOR memory according to at least one embodiment of the present disclosure. FIG. 9 shows an example of a read operation performed on the memory array shown in FIG. 6 by a NOR memory according to at least one embodiment of the present disclosure. The write operation example shown in FIG. 7 or FIG. 8 and the read operation example shown in FIG. 9 may be implemented separately or in combination, and may also be implemented independently or in combination with one or more other embodiments of the present disclosure. The embodiments of the present disclosure do not limit this. In the subsequent exemplary explanation, the implementation of the write operation in FIG. 7 or FIG. 8 and the implementation of the read operation shown in FIG. 9 are combined for exemplary explanation. However, those skilled in the art may understand that this exemplary explanation is not a limitation of the embodiments of the present disclosure. The read/write operation part 710, 810, or 910 may only implement the write operation shown in FIG. 7 or FIG. 8, or only implement the read operation shown in FIG. 9.

It is noted that in all embodiments of the present disclosure, the structures of the read/write operation parts 710, 810, and 910 may be the same or different. Although it is called a read/write operation part, it may be used to perform only a read operation, only a write operation, or both read and write operations.

The following is an example of using a read/write operation part 710, 810, or 910 to illustrate the write and read operations on the circuit diagram shown in FIG. 6. As shown in FIGS. 7-9, the NOR memory according to the embodiment of the present disclosure may also include a read/write operation part 710, 810, or 910 in addition to the memory array of the aforementioned embodiments, for applying corresponding read/write voltages to the respective word lines and bit lines of the memory array to achieve read/write operations.

Although FIGS. 7-9 illustrate the implementation of read/write operations by the same operating part 710, 810, or 910, this disclosure is not limited to this. In some embodiments, separate read operation part and write operation part may also be used to implement read operation and write operation respectively, or in some embodiments, different write operation parts may also be used to implement the two exemplary write operations in FIGS. 7 and 8 respectively. In addition, those skilled in the art may understand that there are various circuit implementations to achieve the read/write operations detailed later. In addition, in some embodiments, an erase operation is required before performing a write operation on the memory array. Although not shown in the drawings, those skilled in the art may understand that the read/write operation part 710, 810, or 910 may also erase the memory transistors in the memory array in various ways. For example, in some embodiments, a gate voltage and a drain voltage required for erasing may be applied simultaneously to all word lines and all bit lines in the memory array, thereby achieving erasure of all memory transistors simultaneously. Please note that in this disclosure, the memory transistor that has undergone erasure processing is considered as storing data “1”, while the memory transistor that has undergone write processing is considered as storing data “0”. That is to say, during the write operation, there is actually no need to perform any write operations on the memory transistor in which data “1” is to be written.

FIG. 7 shows an exemplary write operation 700 for simultaneously writing all memory transistors that share the same word line WL61. FIG. 7 labels “0” or “1” next to each memory transistor to indicate the data to be written in the corresponding memory transistor. As shown in FIG. 7, the word line to be written (and all gate structures connected to this word line) is applied with a gate write voltage Vow, while the remaining word lines are applied with OV voltage. Please note that the 0 V voltage is only an example, and in some embodiments, other gate voltages that do not affect the write operation may also be applied to replace the OV voltage. Regardless of the implementation used, all embodiments of the present disclosure do not limit the magnitudes of the gate write voltage Vow and the gate voltage of the remaining word lines mentioned above, as long as the gate write voltage Vow is greater than the gate voltage threshold value used for the write operation, and the gate voltage of the remaining word lines mentioned above is less than the gate voltage threshold value used for the write operation. In addition, the 12 bit/source lines BL611, BL621, BL631, BL641, BL612, BL622, BL632, BL642, BL613, BL623, BL633, and BL643 of the three memory transistor groups to be written, connected to the same word line WL61, are simultaneously applied with either a source voltage V_{SW} or a bit line write voltage V_{DW}. From FIG. 7, it can be seen that, during the write operation, the four bit/source lines of the same memory transistor group are applied voltage to create a write voltage difference (V_{DW}−V_{SW}) between the two source/drain areas of the memory transistor to be written data “0”, while there is no write voltage difference between the two source/drain areas of the memory transistor to be written data “1”. That is to say, all embodiments of this disclosure do not limit the magnitudes of the aforementioned source voltage V_{SW} and the aforementioned bit line write voltage V_{DW}, as long as the voltage difference (V_{DW}−V_{SW}) between the two is greater than the drain-source voltage (VDs) threshold value used for the write operation. All embodiments of this disclosure do not limit the magnitudes of the voltages respectively applied to the two source/drain areas of the memory transistor to be written data “1”, as long as the drain-source voltage is less than the drain-source voltage threshold value used for the write operation (i.e. there will be no sufficient current flow to achieve writing, thus no write processing will occur). The exemplary voltage difference between the two source/drain areas of the memory transistor to be written data “1” may be 0 V or close to 0 V. The write operation of this disclosure is not limited to this, but may apply appropriate voltage sequences to respective word lines and bit/source lines based on the type of memory transistor or other requirements. The opposite approach may also be adopted, where, during the write operation, there is a write voltage difference (V_{DW}−V_{SW}) greater than the threshold value between the two source/drain areas of the memory transistor to be written data “1”, while there is no write voltage difference greater than the threshold value between the two source/drain areas of the memory transistor to be written data “0”.

FIG. 8 shows another exemplary write operation 800 performed on the circuit diagram shown in FIG. 6, which differs mainly from the write operation 700 in FIG. 7 in that only one memory transistor in the memory transistor group is written at a time, rather than all memory transistors. FIG. 8 indicates “write ‘0”’ next to the memory transistor to be written in each memory transistor group. As shown in FIG. 8, the word line to be written (and all gate structures connected to it) is applied with a gate write voltage V_{GW}, while the remaining word lines are applied with 0 V voltage. Please note that the 0 V voltage is only an example, and in some implementations, other gate voltages that do not affect the write operation may also be applied instead of the 0 V voltage. In addition, the 12 bit/source lines BL611, BL621, BL631, BL641, BL612, BL622, BL632, BL642, BL613, BL623, BL633, and BL643 of the three memory transistor groups to be written, connected to the same word line WL61, are respectively applied with either a source voltage V_{SW} or a bit line write voltage V_{DW}. From FIG. 8, it can be seen that for the same memory transistor group, the source voltage V_{SW} is applied to the source of the memory transistor to be written and all bit/source lines on the same side as this source (i.e. opposite to its drain), while the bit line write voltage V_{DW} is applied to the drain of the memory transistor to be written and all bit/source lines on the same side as this line (i.e. opposite to its source). In other words, during the write operation, the four bit lines of the same memory transistor group are applied with voltage such that there is a write voltage difference (V_{DW}−V_{SW}) between the two source/drain areas of only the memory transistor where data “0” is to be written, while there is no write voltage difference between the two source/drain areas of the other memory transistors so that there is no current flow sufficient. The write operation in this disclosure is not limited to this, but may apply appropriate voltage sequences to respective word lines and bit/source lines based on the type of memory transistor or other requirements. The opposite approach may also be used, where, during the write operation, the four bit/source lines of the same memory transistor group are applied with voltages such that there is a write voltage difference (V_{DW}−V_{SW}) between the two source/drain areas of only the memory transistor where data “1” is to be written, while there is no write voltage difference between the two source/drain areas of the other memory transistors where data “0” is to be written.

FIG. 9 shows an exemplary read operation 900 for reading one memory transistor from all memory transistor groups that share the same word line WL61. FIG. 9 labels “read” next to the memory transistor to be read. As shown in FIG. 9, the word line to be read (and all gate structures connected to this word line) is applied with a gate read voltage VGR, while the remaining word lines are applied with 0 V voltage. Please note that the 0 V voltage is only an example, and in some embodiments, other gate voltages that do not affect the read operation may also be applied instead of the 0 V voltage. In addition, the 12 bit lines BL611, BL621, BL631, BL641, BL612, BL622, BL632, BL642, BL613, BL623, BL633, and BL643 of the three memory transistor groups to be read connected to the same word line WL61 are respectively applied with either a source voltage V_{SR} or a bit line read voltage V_{DR}. From FIG. 9, it can be seen that for the same memory transistor group, the source voltage V_{SR} is applied to the source of the memory transistor to be read and all bit/source lines on the same side as this source (i.e., the side opposite to its drain), while the bit line read voltage V_{DR} is applied to the drain of the memory transistor to be read and all bit/source lines on the same side as this drain (i.e., the side opposite to its source). In other words, the four bit/source lines of the same memory transistor group are applied with voltage such that there is a read voltage difference (V_{DR}−V_{SR}) between the two source/drain contact layers of only the memory transistor to be read so as to achieve read processing, while there is no read voltage difference between the two source/drain contact layers of the remaining memory transistors, so there is no current flow sufficient to achieve reading and it does not affect read processing. The read operation in this disclosure is not limited to this, but may apply appropriate voltage sequences to respective word lines and bit/source lines based on the type of memory transistor or other requirements.

By utilizing the write operation 700 or 800 shown in FIG. 7 or FIG. 8, and/or the read operation 900 shown in FIG. 9 as described above, it is possible to easily and quickly implement the write and/or read operations for the memory arrays in various embodiments of the present disclosure. That is to say, one or more of the circuit structures and the read/write operations shown in FIGS. 6-9 can be combined with the NOR memory device structure shown in any previous embodiment.

In addition, in some embodiments, in order to further reduce the horizontal size of the memory array, the isolation parts between adjacent columns in the memory array as shown in FIGS. 3A-3C, FIGS. 4A-4C, or FIGS. 5A-5D may also be removed. That is to say, an improved arrangement of memory arrays may be proposed, which can reduce the area occupied by the entire memory array in the horizontal plane and further increase the array density.

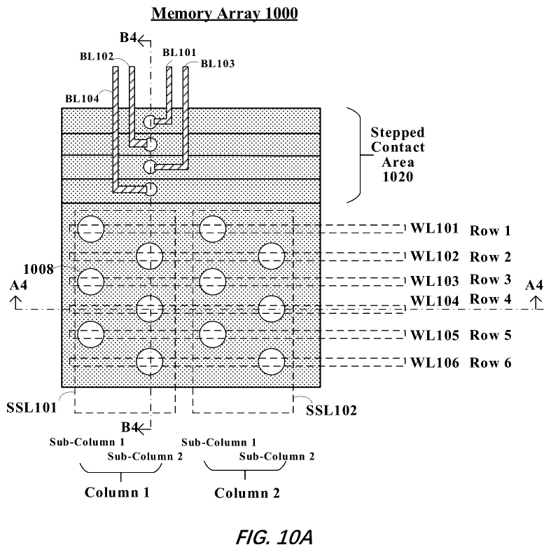

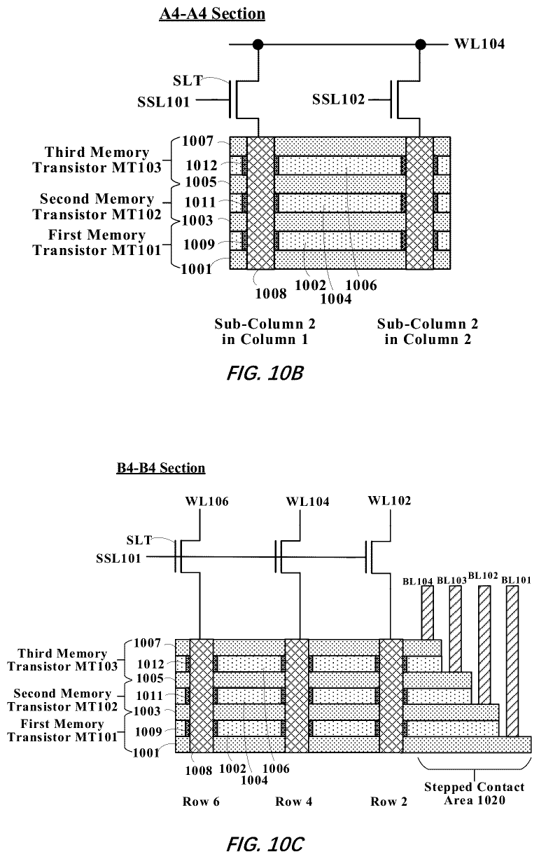

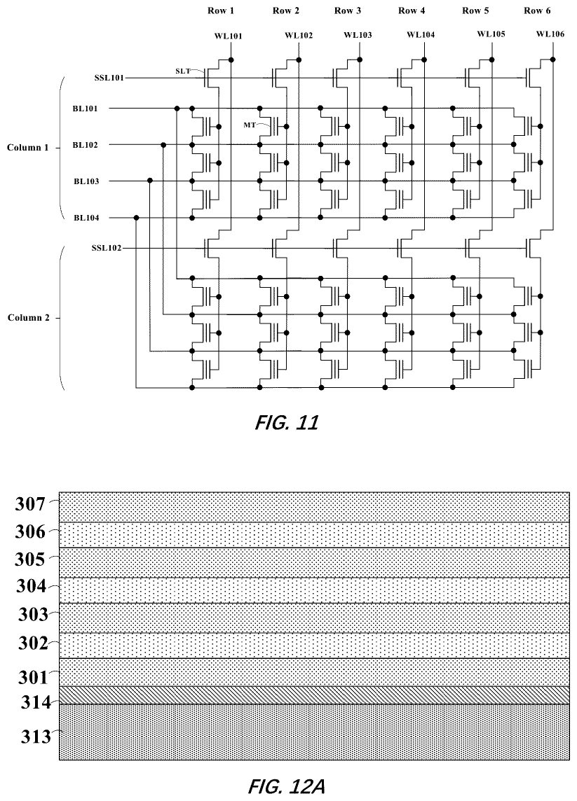

FIG. 10A shows a schematic plan view of an array composed of NOR memory devices according to at least one embodiment of the present disclosure, FIG. 10B shows a schematic cross-sectional view taken along the dashed lines A4-A4 in FIG. 10A, FIG. 10C shows a schematic cross-sectional view taken along the dashed lines B4-B4 in FIG. 10A, and FIG. 11 exemplarily illustrates a circuit schematic diagram of the memory array shown in FIGS. 10A-10C.

In FIGS. 10A-10C, the isolation parts between the columns are removed from the memory array as shown in the embodiment shown in FIG. 5A. However, please note that the structure shown in FIGS. 10A-10C, which removes the inter-column isolation parts, may be implemented in combination with any of the memory array structures in the aforementioned embodiments, and may also be applicable to other memory array structures.

Due to the fact that the memory array 1000 in FIGS. 10A-10C does not have isolation parts between adjacent columns as in the aforementioned embodiments, there is no isolation between the source/drain contact layers of the memory transistors at respective stack layers in the respective memory transistor groups in the columns, and it is not possible to apply a bit line voltage or a source line voltage separately to the memory transistors in each column.

Therefore, as shown in FIGS. 10A-10C, all columns in the memory array 1000 share the four bit lines BL101-BL104 led out in the stepped contact area 1020. Therefore, the memory array 1000 cannot uniquely locate one memory transistor group solely through its bit line and word line as in the aforementioned embodiments. Therefore, in one possible implementation, as shown in the cross-sectional views of FIGS. 10B-10C as well as the circuit diagram of FIG. 11, the gate structures of the respective memory transistor groups are not directly connected to the respective word lines, but are connected to the respective word lines through respective selection transistors SLT. One of source/drain electrodes of each selection transistor SLT is connected to the gate of its corresponding memory transistor group, while the other source/drain electrode is connected to the word line WL of the row to which the memory transistor group belongs, and its gate electrode is connected to a selection line SSL of the column to which the memory transistor group belongs. As shown in the circuit diagram of FIG. 11, the gates of the selection transistors of the memory transistor groups in the same column are all connected to the same selection line SSL101 or SSL102; and in one implementation, the voltage on the selection line of the selected column may be made high, so that the selection transistors of that column are all turned on, thereby conducting the voltages on the word lines of all rows to the gates of the memory transistor groups of all rows, while the voltage on the selection line of the unselected column is low voltage that fails to turn on the selection transistor, so that the unselected column cannot receive the voltage applied on the word lines.

In the schematic plan view shown in FIG. 10A, dashed boxes are used to represent the word lines WL101-WL106 for respective rows and the selection lines SSL101-SSL102 for respective columns. By using the word lines and selection lines, one memory transistor group at the overlap of one word line and one selection line may be uniquely selected. In one possible implementation, each selection transistor SLT may have the same structure as ordinary MOS transistors. The selection transistors may be fabricated on a chip same as or different from that of the memory array 1000. For example, the selection transistors may be directly fabricated above the upper surfaces of the gate structures of the respective memory transistor groups, or may be fabricated in the peripheral area around the memory array 1000 in the same chip, or may be fabricated on another chip and connected to the gate structures of the respective memory transistor groups in various ways. The word lines and selection transistors SLT may be fabricated in various structural ways in various regions, without necessarily being fabricated above the memory array 1000. Therefore, in the cross-sectional views of FIGS. 10B and 10C, the part including the word lines and the selection transistors is represented by circuit symbols instead of cross-sectional diagrams.

In some embodiments, as shown in FIGS. 10B and 10C which show the cross-sectional views, each memory transistor group in the memory array 1000 may include three vertically stacked memory transistors (i.e., the first to third memory transistors MT101-MT103), whose main difference from the structure of the memory transistor groups shown in the cross-sectional views of the aforementioned embodiments is that, there is no isolation part between adjacent columns, so there is no isolation between the source/drain contact layers of the memory transistors in adjacent columns at the same stack layer. Other specific constructions may refer to those in the previous embodiments, and will not be further elaborated here. Those skilled in the art may understand that this disclosure is not limited to the construction of the memory transistor group mentioned above, and memory transistor groups with any other construction may also be used.

The write/read operations of the memory array 1000 shown in FIGS. 10A-10C may refer to the content of the write/read operations described earlier in conjunction with FIGS. 7-9, but other suitable write/read operations may also be used, and thus those operations will not be repeated here.

Taking the memory array shown in FIGS. 3A-3C and the memory array shown in FIGS. 4A-4C as examples respectively, combined with the accompanying drawings, the manufacturing process of the memory device according to the present disclosure will be described in detail. Please note that these manufacturing processes are only for illustrative purposes and not limitations on the present disclosure. The order of these process steps is not limited by the examples provided in the drawings, but may be adjusted as needed. Please note that these manufacturing processes may be appropriately modified as needed to be applicable to various embodiments disclosed herein. These manufacturing processes may be used to manufacture the memory arrays of the embodiments of the present disclosure, and to manufacture memory arrays of other structures, and are not limited in this disclosure.

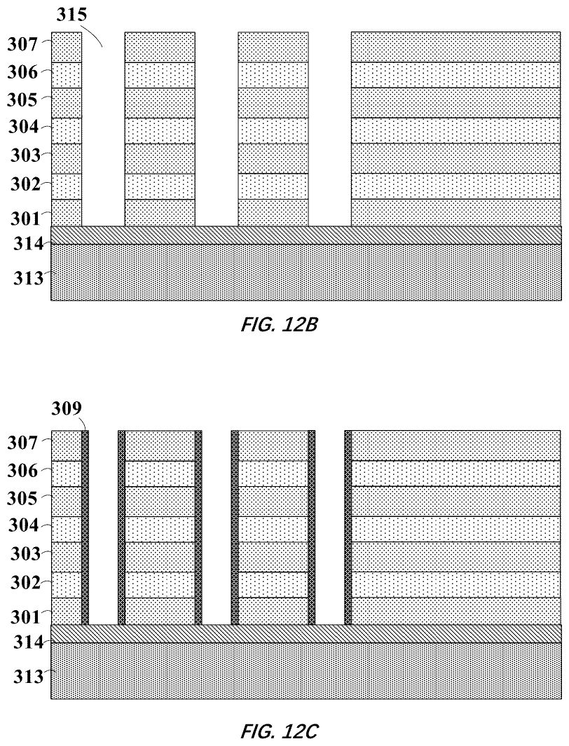

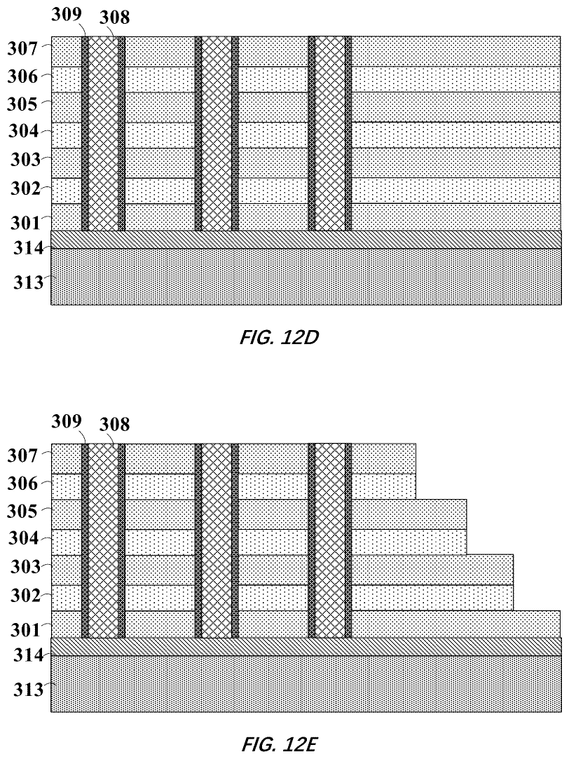

FIGS. 12A-12G are cross-sectional views schematically illustrating respective steps of a method for manufacturing a NOR memory device according to at least one embodiment of the present disclosure, wherein the specific construction of the NOR memory device corresponds to the construction in the embodiment shown in FIGS. 3A-3C. Unless otherwise specified, the cross-sectional views of the respective steps in FIGS. 12A-12G correspond to the B-B cross-sectional view in FIG. 3C. Please note that the manufacturing processes shown in FIGS. 12A-12G may also be applicable to the specific structures of memory devices described in other embodiments of the present disclosure, and the number of alternately stacked layers, or the arrangement of gate structures on the horizontal plane may be adjusted as needed, or the process steps of forming isolation parts between adjacent columns may not be performed as needed.

As shown in FIG. 12A, firstly, multiple source/drain contact layers and multiple isolation layers are alternately stacked on the substrate 313, namely, the first source/drain contact layer 301, the first isolation layer 302, the second source/drain contact layer 303, the second isolation layer 304, the third source/drain contact layer 305, the third isolation layer 306, and the fourth source/drain contact layer 307. In some implementations, these layers may be sequentially deposited by using various deposition processes, such as chemical vapor deposition (CVD).

In some embodiments, the substrate 313 may be a silicon substrate, such as a silicon wafer. In order to isolate the influence of the substrate on the device formed above, an insulating material layer 314 may also be formed between the substrate 313 and the first source/drain contact layer 301.

As described in the previous embodiments, the number of alternately stacked source/drain contact layers and isolation layers may be set as needed. For example, it is possible to stack (h+1) source/drain contact layers and h isolation layers alternately in the vertical direction, thereby forming h vertically stacked memory transistors, where h is a natural number greater than 1.

In some embodiments, each source/drain contact layer may include polysilicon or may be a polysilicon layer. In some embodiments, each isolation layer may include a silicon oxide or may be a silicon oxide layer. In some implementations, the thickness of each source/drain contact layer or each isolation layer may be within the range of 10-200 nm (including endpoint values). Please note that this disclosure is not limited to the aforementioned exemplary materials and thickness values, but rather allows for the selection of various suitable materials and thicknesses as needed. In addition, the materials of the respective source/drain contact layers may be the same or different from each other, and the materials of the respective isolation layers may also be the same or different from each other. Each of the source/drain contact layers and the isolation layers may be a layer composed of a single material, or a composite layer composed of multiple materials.

Next, as shown in FIG. 12B, multiple gate holes 315 are formed, extending vertically through the respective source/drain contact layers and isolation layers. For example, as shown in FIG. 3A, multiple gate holes 315 may be arranged in an n*m array on a horizontal plane, where n and m are natural numbers greater than 1. Please note that the arrangement of gate holes 315 on the horizontal plane is not limited to this, but other suitable arrangements may be used, such as those arrangements similar to those shown in FIGS. 5A and 5B. Please note that in this disclosure, the “gate hole” refers to a hole used to form a gate structure, but the gate hole is not limited to only forming a gate structure therein. As will be described later, the desired semiconductor layer may also be formed in the gate hole.

In some embodiments, the positions of the gate holes 315 may be defined by photolithography. That is to say, photoresist covers the surface except for the areas where the respective gate holes 315 are to be formed, and thus the areas where the respective gate holes 315 are to be formed are exposed; then the areas where the respective gate holes 315 are to be formed are subjected to etching treatment (such as reactive ion etching (RIE)) until all source/drain contact layers and isolation layers are penetrated, thereby forming the gate holes 315. In some embodiments, the diameter of each gate hole 315 may be between 30-300 nm.

Next, as shown in FIG. 12C, a semiconductor layer 309 is formed in the gate hole 315.

In some embodiments, semiconductor material may be deposited in the respective gate holes, so as to continuously cover the sidewalls of the respective source/drain contact layers and the respective isolation layers, thereby forming semiconductor layers 309 that are continuous with each other, which thus may also be referred to as a continuous semiconductor layer 309. As mentioned earlier, in the memory transistor group corresponding to each gate hole (where a gate structure will be formed later), three vertically stacked memory transistors share the continuous semiconductor layer 309.

In some implementations, polysilicon material may be deposited through CVD processing, and the polysilicon material on unexpected parts may be removed, thereby forming semiconductor layers 309. The thickness of the deposited semiconductor layers 309 may be the desired channel thickness for the memory transistor, for example, between 10-100 nm. Please note that the material of the semiconductor layers 309 is not limited to polysilicon, but may also be other suitable semiconductor material. Although FIG. 12C shows that the semiconductor layers 309 are not formed on the portions of the insulation layer 314 exposed through the gate holes, this disclosure is not limited to this. It is also possible to form the semiconductor layers 309 on all the portions of the insulation layer 314 exposed through the gate holes, which usually does not affect the operation of the memory transistors.

Next, as shown in FIG. 12D, in the respective gate holes 315, respective gate structures 308 are formed on the corresponding semiconductor layers 309.

In some embodiments, in the respective gate holes 315, layers contained in the gate structure 308 are sequentially formed on the respective semiconductor layers 309, thereby forming the gate structure 308. For example, one of the gate structures 308 may include an ONO (oxide-nitride-oxide) stacked layer for storing charges, and a gate electrode layer. On the semiconductor layer 309, a tunneling oxide layer is grown or deposited firstly, subsequently a nitride layer for storing charges is deposited, then an oxide layer is deposited, and finally a metal (such as tungsten) or polysilicon is deposited so as to fill the gate hole 315, thereby forming a gate electrode.

Next, as shown in FIG. 12E, steps are formed at one end of each column of source/drain contact layers, so that all source/drain contact layers are partially exposed in the horizontal plane, as shown in the plan view of FIG. 3A, to facilitate the formation of contacts on the exposed portions for connecting the metal lines of the respective bit/source lines.

In some implementations, the steps may be formed by step etching and trimming processing. Please note that although not shown in the drawings, the steps may also be formed at both ends of each column of source/drain contact layers, thus the same source/drain contact layer will be connected to the corresponding bit/source line from both ends simultaneously in the future.

Next, as shown in FIG. 12F, spacers 317 are formed on the sidewalls of the respective steps, and metal silicides 316 are formed on the exposed surfaces of the respective source/drain contact layers.

In some embodiments, self-aligned block (SAB) processing may be used to form the sidewall spacers 317 and the self-aligned metal silicides 316. In some embodiments, the spacer 317 may include silicon oxide, or silicon nitride, or a combination of both.

Next, as shown in FIG. 12G, an interlayer dielectric layer 310 is formed, in which holes are formed and then filled by metal material, so as to form respective contacts 318.

In some embodiments, a flat interlayer dielectric layer 310 may be formed by depositing electrical insulating material and then performing chemical mechanical polishing (CMP). Then, in the interlayer dielectric layer 310, holes are formed by etching. At this time, the surfaces of the respective steps and the gate metal layers serve as etch stop layers, so that the etching stops on the surfaces of these layers, thereby forming the required holes. Then metal material (such as tungsten) is deposited in the respective holes so as to form the respective contacts 318.

Those skilled in the art may understand that a metal layer (including, for example, word lines, bit/source lines, etc.) connected to the respective contacts 318 will be formed subsequently, and its process is omitted here.

In addition, as shown in FIGS. 3A and 3B, an isolation part is arranged between the memory transistor groups formed by adjacent columns of the gate structures, to isolate the source/drain contact layers of the memory transistors in different columns, thereby separating the bit/source lines used for the memory transistors in different columns. Therefore, although not shown before, trench isolation processing may be performed after any of the steps in FIGS. 12A-12G, in order to form an isolation part between adjacent columns. For example, in some embodiments, a trench penetrating all the source/drain contact layers may be formed between adjacent columns of the gate holes or their corresponding formed gate structures, and insulating material may be filled in the trench to form an isolation part, so that the respective source/drain contact layers in the memory transistors formed by adjacent columns of the gate holes are isolated from each other. The construction of the isolation part may refer to the construction shown in FIGS. 3A and 3B, and will not be repeated here.

Please note that the processes described in the previous steps are only illustrative and not restrictive. This disclosure may employ various other suitable process treatments to achieve each step.

Please note that the sequence of process steps shown before is only illustrative and not restrictive. This disclosure may adjust the order of each process step as needed. For example, the steps of forming the stepped contact area (as shown in FIGS. 12E-12G) may be interspersed with the steps of forming the gate structures and the semiconductor layers (as shown in FIGS. 12B-12D) in any order, or all of the steps of forming the stepped contact area may be performed before the steps of forming the gate structures and the semiconductor layers. For example, the step of forming the steps in FIG. 12E, the step of forming the spacers and the metal silicides in FIG. 12F, or the step of forming the ILD layer and the contacts in FIG. 12G may be performed following the step of FIG. 12A, the step of FIG. 12B, the step of FIG. 12C, or the step of FIG. 12D. Due to the simple structure and simple manufacturing process of the memory device of the present disclosure, the manufacturing procedure may be flexibly set.

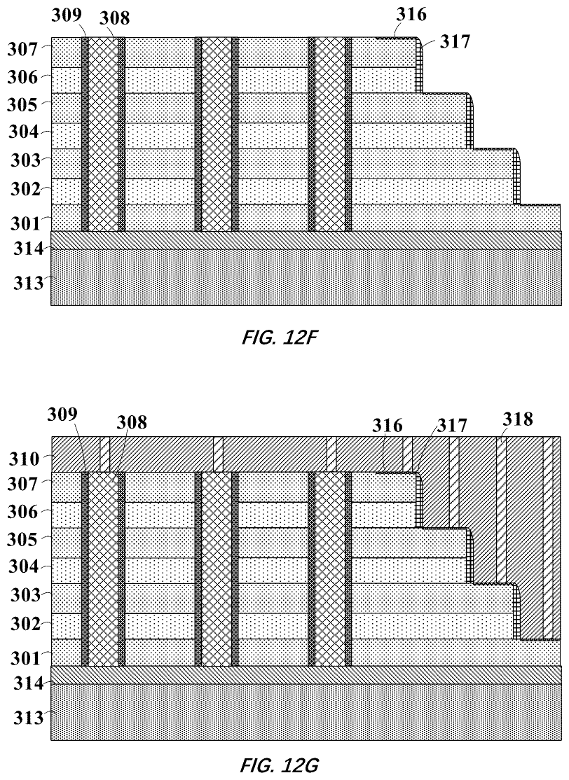

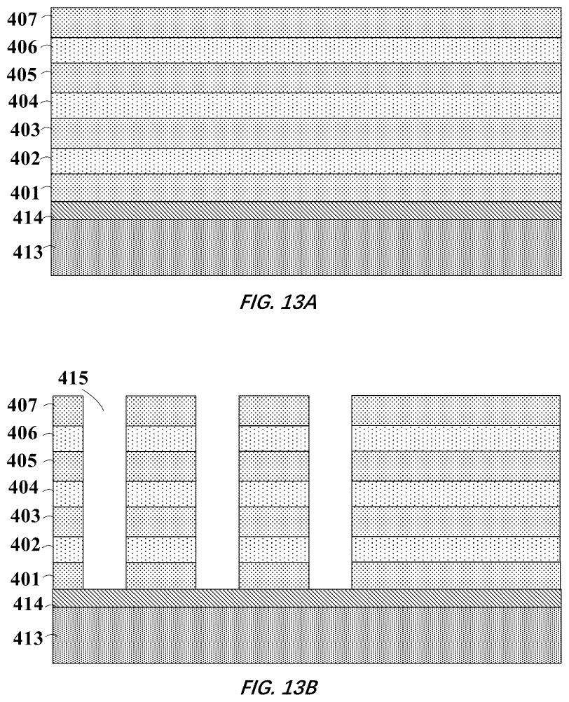

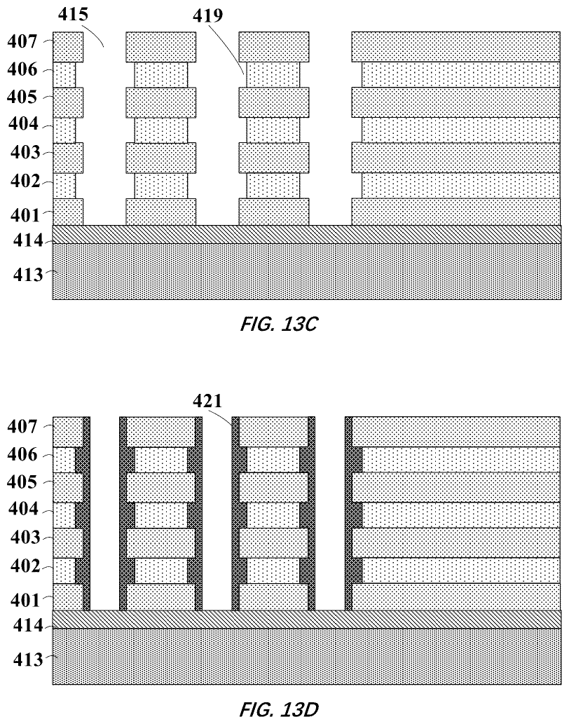

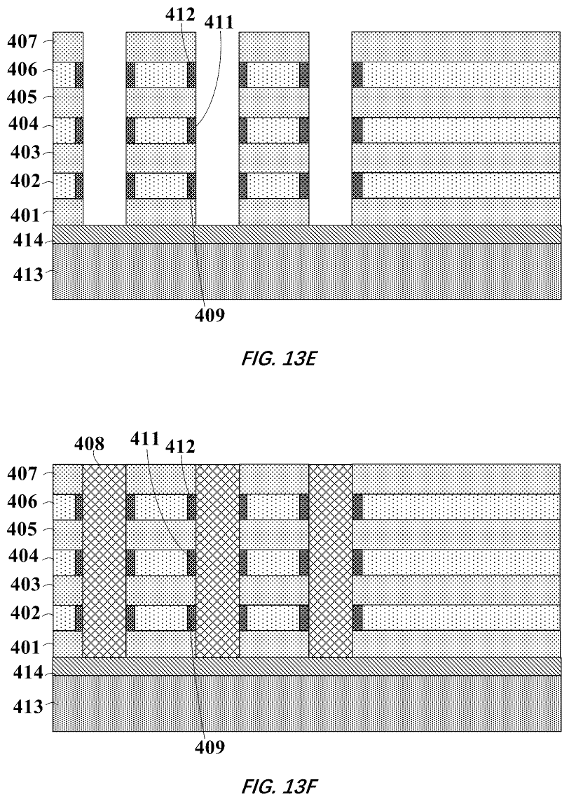

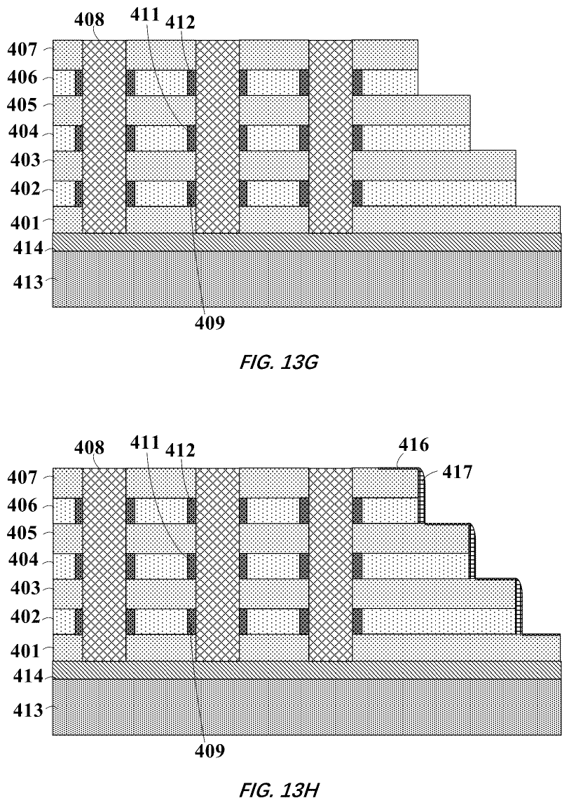

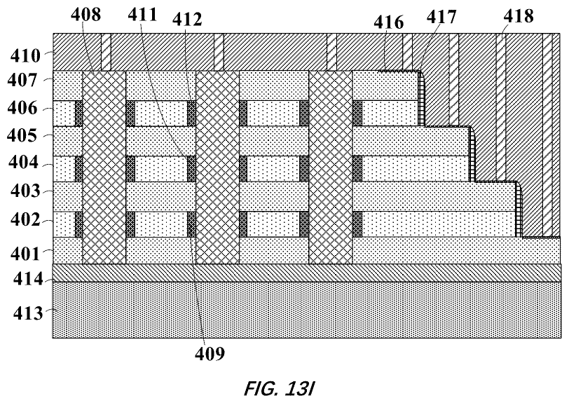

FIGS. 13A-13I are cross-sectional views schematically illustrating respective steps of a method for manufacturing a NOR memory device according to at least one embodiment of the present disclosure, wherein the specific construction of the NOR memory device corresponds to the construction in the embodiment shown in FIGS. 4A-4C. Unless otherwise specified, the cross-sectional views of the respective steps in FIGS. 13A-13I correspond to the B2-B2 cross-sectional view in FIG. 4C. Please note that the manufacturing processes shown in FIGS. 13A-13I may also be applicable to the specific structures of memory devices described in other embodiments of the present disclosure, and the number of alternately stacked layers, or the arrangement of gate structures on the horizontal plane may be adjusted as needed, or the process steps of forming isolation parts between adjacent columns may not be performed as needed.

Since the main difference between the memory device construction in the embodiment shown in FIGS. 4A-4C and the memory device construction in the embodiment shown in FIGS. 3A-3C lies in the arrangement of semiconductor layers in the vertically stacked memory transistors, the main difference between the manufacturing processes shown in FIGS. 13A-13I and the manufacturing processes shown in FIGS. 12A-12G lies in the steps of forming the semiconductor layers, while other steps shown in FIGS. 13A-13I may refer to the corresponding steps in FIGS. 12A-12G, and some content will not be repeated.

As shown in FIG. 13A, firstly, multiple source/drain contact layers and multiple isolation layers are alternately stacked on the substrate 413, namely, the first source/drain contact layer 401, the first isolation layer 402, the second source/drain contact layer 403, the second isolation layer 404, the third source/drain contact layer 405, the third isolation layer 406, and the fourth source/drain contact layer 407. In some implementations, these layers may be sequentially deposited by using various deposition processes, such as chemical vapor deposition (CVD).

The specific descriptions of the substrate 413, the insulating material layer 414 on it, the source/drain contact layers, and the isolation layers may refer to the step shown in FIG. 12A, and will not be repeated here.

Next, as shown in FIG. 13B, multiple gate holes 415 are formed, extending vertically through the respective source/drain contact layers and isolation layers. For example, as shown in FIG. 4A, multiple gate holes 415 may be arranged in an n*m array on a horizontal plane, where n and m are natural numbers greater than 1. Please note that the arrangement of gate holes 415 on the horizontal plane is not limited to this, but other suitable arrangements may be used, such as those arrangements similar to those shown in FIGS. 5A and 5B.

The specific description of the step of forming the gate holes 415 may refer to the description of the step shown in FIG. 12B, and will not be repeated here.

Next, as shown in FIG. 13C, selective etching is performed on the isolation layers exposed through the respective gate holes 415, so that the sidewalls of the isolation layers are recessed in the horizontal direction relative to the sidewalls of the source/drain contact layers, thereby forming a recess 419 as shown in the drawing.

In some embodiments, the selective etching processing may be carried out through wet etching, for example, etching only the material of the isolation layers exposed in the respective gate holes without etching the material of the respective source/drain contact layers, or having a high etching selectivity ratio for the material of the isolation layers to the material of the respective source/drain contact layers. The wet etching time may be controlled, so as to control the depth of the recess 419, thereby defining the thickness of the channel to be formed subsequently, for example, 10-100 nm.

Next, as shown in FIG. 13D, semiconductor material 421 is deposited in the respective gate holes, so as to continuously cover the sidewalls of the respective source/drain contact layers and the respective isolation layers. At this time, the semiconductor material 421 fills the respective recesses 419 formed in the previous step.

In some embodiments, polysilicon material may be deposited as the semiconductor material 421 through CVD processing. Please note that the semiconductor material 421 is not limited to polysilicon, but may also be other suitable semiconductor material. Although FIG. 13D shows that no semiconductor material 421 has been formed on the source/drain contact layer 407 at the top and on the portions of the insulation layer 414 exposed through the gate holes, this disclosure is not limited to this. The semiconductor material 421 may be deposited also on the source/drain contact layers 407 and on all the portions of the insulation layer 414 exposed through the gate holes, and in subsequent step the semiconductor material 421 on these portions may be removed.

Next, as shown in FIG. 13E, the semiconductor material 421 is etched back, so as to remove the semiconductor material located on the sidewalls of the respective source/drain contact layers, and remain the semiconductor material located on the sidewalls of the respective isolation layers as the semiconductor layers 409, 411, and 412 spaced apart from each other.

In some embodiments, the semiconductor material 421 may be etched back by wet etching, and after the wet etching, the gate holes 415 may be further performed by RIE processing as needed, so as to form a flat hole wall.

Next, as shown in FIG. 13F, in the respective gate holes 415, respective gate structures 408 are formed, so that the gate structures 408 contact the sidewalls of the respective source/drain contact layers and the semiconductor layers 409, 411, and 412. The specific description of the process in this step may refer to the description of the step shown in FIG. 12D, and will not be repeated here.

Next, as shown in FIG. 13G, steps are formed at one end of each column of source/drain contact layers, so that all source/drain contact layers are partially exposed in the horizontal plane, as shown in the plan view of FIG. 4A, to facilitate the formation of contacts on the exposed portions for connecting the metal lines of the respective bit/source lines. The specific description of the process in this step may refer to the description of the step shown in FIG. 12E, and will not be repeated here.

Next, as shown in FIG. 13H, spacers 417 are formed on the sidewalls of the respective steps, and metal silicides 416 are formed on the exposed surfaces of the respective source/drain contact layers. The specific description of the process in this step may refer to the description of the step shown in FIG. 12F, and will not be repeated here.

Next, as shown in FIG. 13I, an interlayer dielectric layer 410 is formed, in which holes are formed and then filled by metal material, so as to form respective contacts 418. The specific description of the process in this step may refer to the description of the step shown in FIG. 12G, and will not be repeated here.

Those skilled in the art may understand that a metal layer (including, for example, word lines, bit/source lines, etc.) connected to the respective contacts 418 will be formed subsequently, and its process is omitted here.

In addition, as shown in FIGS. 4A and 4B, an isolation part is arranged between the memory transistor groups formed by adjacent columns of the gate structures, to isolate the source/drain contact layers of the memory transistors in different columns, thereby separating the bit/source lines used for the memory transistors in different columns. Therefore, although not shown before, trench isolation processing may be performed after any of the steps in FIGS. 13A-13I, in order to form an isolation part between adjacent columns. For example, in some embodiments, a trench penetrating all the source/drain contact layers may be formed between adjacent columns of the gate holes or their corresponding formed gate structures, and insulating material may be filled in the trench to form an isolation part, so that the respective source/drain contact layers in the memory transistors formed by adjacent columns of the gate holes are isolated from each other. The construction of the isolation part may refer to the construction shown in FIGS. 4A and 4B, and will not be repeated here.

Please note that the processes described in the previous steps are only illustrative and not restrictive. This disclosure may employ various other suitable process treatments to achieve each step.

Please note that the sequence of process steps shown before is only illustrative and not restrictive. This disclosure may adjust the order of each process step as needed. For example, the steps of forming the stepped contact area (as shown in FIGS. 13G-13I) may be interspersed with the steps of forming the gate structures and the semiconductor layers (as shown in FIGS. 13B-13F) in any order, or all of the steps of forming the stepped contact area may be performed before the steps of forming the gate structures and the semiconductor layers. For example, the step of forming the steps in FIG. 13G, the step of forming the spacers and the metal silicides in FIG. 13H, or the step of forming the ILD layer and the contacts in FIG. 13I may be performed following the step of FIGS. 13A, the step of FIG. 13B, the step of FIG. 13C, the step of FIG. 13D, the step of FIG. 13E, or the step of FIG. 13F. Due to the simple structure and simple manufacturing process of the memory device of the present disclosure, the manufacturing procedure may be flexibly set.

In addition, the above-described NOR memory devices or memory arrays as well as corresponding NOR memories according to the embodiments of the present disclosure may be applied to various electronic devices with memory needs, such as smartphones and their peripheral electronic devices (such as Bluetooth headphones and wearable devices and the like), electronic devices using the Internet of Things, in-vehicle electronic devices and the like.

Those skilled in the art may understand that appropriate modifications can be made to various above-described circuit structures of the present disclosure as needed, all of which are within the scope of protection of the present disclosure.

Various embodiments of the present disclosure have been described above, and the foregoing descriptions are exemplary, not exhaustive, and not limiting of the disclosed embodiments. Numerous modifications and variations will be apparent to those of ordinary skill in the art without departing from the scope and spirit of the described embodiments. The terminology used herein was chosen to best explain the principles of the various embodiments, the practical application or improvement over the technology in the marketplace, or to enable others of ordinary skill in the art to understand the various embodiments disclosed herein.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

What is claimed is:

1. A NOR memory device comprising:
at least two source/drain contact layers and at least one isolation layer alternately stacked in a vertical direction;
a gate structure vertically extending through the source/drain contact layers and the isolation layer; and
a semiconductor layer on the periphery of the gate structure;
wherein, two of the source/drain contact layers located immediately above and below the isolation layer are respectively connected to two bit/source lines, and form a memory transistor together with the gate structure and the semiconductor layer.

2. The NOR memory device according to claim 1, wherein,
the source/drain contact layers and the isolation layer alternately stacked in the vertical direction include h+1 source/drain contact layers and h isolation layers, respectively, where h is a natural number greater than 1;
the periphery of the gate structure is provided with the semiconductor layer;
each of the source/drain contact layers is connected to its respective different bit/source line; and
two of the source/drain contact layers located immediately above and below each isolation layer, the gate structure, and the semiconductor layer located between the corresponding isolation layer and the gate structure form a corresponding memory transistor, thereby h vertically stacked memory transistors are formed.

3. The NOR memory device according to claim 1, wherein,
the semiconductor layer is arranged between the gate structure and the source/drain contact layers, and between the gate structure and the isolation layer, and extends continuously along the vertical direction on the periphery of the gate structure.

4. The NOR memory device according to claim 1, wherein,
the semiconductor layer comprises multiple semiconductor sublayers distributed at intervals along the vertical direction and arranged between respective isolation layer and the gate structure.

5. The NOR memory device according to claim 4, wherein,
the gate structure contacts sidewalls of the source/drain contact layers;
a recess is provided at the end of the isolation layer facing the gate structure and extends away from the gate structure; and
the semiconductor layer is arranged inside the recess and in contact with the gate structure and the isolation layer.

6. The NOR memory device according to claim 1, wherein,
the NOR memory device comprises multiple gate structures arranged in n rows and m columns on a horizontal plane, the gate structures vertically extending through the source/drain contact layers and the isolation layer, where n and m are natural numbers greater than 1;
part or all of the gate structures in a same row are connected to a same word line;
part or all of the source/drain contact layers located at a same vertical layer in the memory transistors formed by the gate structures in a same column are connected to a same bit/source line; and
the source/drain contact layers located at a same vertical layer in the memory transistors formed by adjacent columns of the gate structures are isolated from each other.

7. The NOR memory device according to claim 6, wherein,
the memory transistors formed by the gate structures in the same column share the source/drain contact layers, and one or two ends of the source/drain contact layers of each column are provided with a contact for connecting a metal line of the respective bit/source line.

8. The NOR memory device according to claim 6, wherein,
at least one column of the gate structures includes i sub-columns of the gate structures, where i is a natural number greater than 1;
the gate structures of at least two adjacent sub-columns are spaced in the column direction.

9. The NOR memory device according to claim 8, wherein,
each gate structure in the i sub-columns has a same distance from each of the gate structures adjacent to it in the column direction;
or,
each gate structure in the i sub-columns has a same distance from each of the gate structures adjacent to it in the row direction;
or,
each gate structure in the i sub-columns has a same distance from each of the gate structures adjacent to it in the row or column direction.

10. The NOR memory device according to claim 1, wherein,
the source/drain contact layer is a metal layer or a polysilicon layer, or the source/drain contact layer is made of a material containing metal or polysilicon.

11. The NOR memory device according to claim 1, wherein,
the isolation layer is a silicon oxide layer or a silicon nitride layer, or the isolation layer is made of a material containing silicon oxide or silicon nitride.

12. The NOR memory device according to claim 1, wherein,
the semiconductor layer is a polysilicon layer, or the semiconductor layer is made of a material containing polysilicon.

13. A method of manufacturing a NOR memory device, comprising:
forming, over a substrate, at least two source/drain contact layers and at least one isolation layer alternately stacked in a vertical direction;
forming a gate hole that extends vertically through the source/drain contact layers and the isolation layer;
forming, in the gate hole, a gate structure and a semiconductor layer on the periphery of the gate structure; and
connecting two of the source/drain contact layers located immediately above and below the isolation layer to two bit/source lines respectively;
wherein, the two source/drain contact layers located immediately above and below the isolation layer form a memory transistor together with the gate structure and the semiconductor layer.

14. The method according to claim 13, wherein,
the source/drain contact layers and isolation layer alternately stacked in the vertical direction include h+1 source/drain contact layers and h isolation layers, respectively, where h is a natural number greater than 1;
the periphery of the gate structure is provided with the semiconductor layer;
each of the source/drain contact layers is connected to its respective different bit/source line; and
two of the source/drain contact layers located immediately above and below each isolation layer, the gate structure, and the semiconductor layer located between the corresponding isolation layer and the gate structure form a corresponding memory transistor, thereby h vertically stacked memory transistors are formed.

15. The method according to claim 14, wherein,
the step of forming, in the gate hole, a gate structure and a semiconductor layer on the periphery of the gate structure includes:
depositing, in the gate hole, semiconductor material continuously covering the sidewall of the gate hole, so as to form the semiconductor layer continuously covering the ends of the source/drain contact layers and the isolation layer facing the gate hole; and
forming, in the gate hole, the gate structure on the semiconductor layer.

16. The method according to claim 13, wherein,
the step of forming, in the gate hole, a gate structure and a semiconductor layer on the periphery of the gate structure includes:
selectively etching the isolation layer exposed by the gate hole, so as to provide a recess at the end of the isolation layer facing the gate hole, the recess extending away from the gate hole;
depositing, in the gate hole, semiconductor material continuously covering the sidewall of the gate hole, so as to form a continuous semiconductor layer continuously covering the ends of the source/drain contact layers and the isolation layer facing the gate hole;
etching back the semiconductor material, so as to remove the semiconductor material on the ends of the source/drain contact layers facing the gate hole, and remain the semiconductor material located in the recess at the end of the isolation layer as the semiconductor layer; and
forming, in the gate hole, the gate structure such that the gate structure contacts the sidewalls of the source/drain contact layers and the semiconductor layer.

17. The method according to claim 13, wherein,
the source/drain contact layer is a metal layer or a polysilicon layer, or the source/drain contact layer is made of a material containing metal or polysilicon.

18. The method according to claim 13, wherein,
the isolation layer is a silicon oxide layer or a silicon nitride layer, or the isolation layer is made of a material containing silicon oxide or silicon nitride.

19. The method according to claim 13, wherein,
the semiconductor layer is a polysilicon layer, or the semiconductor layer is made of a material containing polysilicon.
